(19) United States
(12) Patent Application Publication
(10) Pub. No.: US 2012/0320556 A1
(43) Pub. Date: Dec. 20, 2012

(54) FRAME MEMBER, FRAME UNIT, MOUNTING BOARD UNIT, AND MANUFACTURING METHOD

(75) Inventor: Toshinobu Ogatsu, Tokyo (JP)

(73) Assignee: NEC CORPORATION, Tokyo (JP)

(21) Appl. No.: 13/579,163

(22) PCT Filed: Jan. 26, 2011
(86) PCT No.: PCT/JP2011/000397

§ 371 Date: Aug. 15, 2012

(30) Foreign Application Priority Data
Apr. 2, 2010 (JP) 2010-086154

(51) Int. Cl. H05K 7/14; H05K 3/36

(52) U.S. Cl. 361/813; 211/26; 29/830

(57) ABSTRACT

Provided are a frame member having a reduced height, a frame unit, a mounting board unit, and a manufacturing method. The frame unit is to be attached to a board (200) on which an electronic component (210) is mounted and includes a frame member (120) having a side wall (123) to be connected to the board (200) and a first protruding portion (121) protruding inward or outward from the side wall, and a first member (110) detachably attached to the frame member and having a second protruding portion protruding toward the frame member to fit with the first protruding portion (121).

### TECHNICAL FIELD

The present invention relates to a frame member, a frame unit, a mounting board unit, and a manufacturing method thereof and, particularly, to a frame member that is attached to a mounting board on which an electronic component is mounted, a frame unit, a mounting board unit to which the frame member is attached, and a manufacturing method thereof.

### BACKGROUND ART

Portable equipment such as mobile telephones, personal digital assistants and notebook personal computers are widely used today. The portable equipment are becoming multifunctional beyond their basic functions of telephone conversation feature, scheduling management, document preparation and the like. For example, more and more functions such as email sending and receiving, web browsing, game function and television viewing on a mobile telephone are added. As a consequence, portable equipment have deeply penetrated as an indispensable tool to everyday life.

With such expansion and advancement of functionality, antennas for additional functions that emit different radio waves are mounted in addition to an antenna for telephone communication on a personal digital assistant. For example, a television antenna, Bluetooth antenna, GPS (Global Positioning System) antenna, RFID (Radio Frequency IDentification) antenna and the like are mounted. According to uses of those antennas, radio waves with different frequencies are used. Thus, the operating clock frequency of a LSI (Large Scale Integrated Circuit) becomes higher, resulting in electrically overcrowded conditions. In such conditions, electronic components that are placed on a printed board of a personal digital assistant are likely to have an adverse effect on each other. For this reason, a shield member that provides electromagnetic shielding between the electronic components is required.

On the other and, the portable equipment cannot be infinitely enlarged in size for their product nature of being always carried along. Upsizing due to the expansion and advancement of functionality significantly degrades the portability, which is unacceptable to users. Being small and thin is an important factor for portable terminals. Therefore, further reduction in size and height and integration of functions are required for each component of a personal digital assistant.

Under these circumstances, reduction in size and thickness is under way in the shield member, which is mentioned earlier, as well. As a technique for size reduction, a method of using one shield member, rather than separate shield members, to cover different functions and mounted components all together is often employed. A plurality of shield members are integrated into one large shield member. Thus, the outer dimensions of a single shield member increase. However, because the number of shield members decreases, the mounting area required for the shield member can be reduced overall in the mounting board as a whole.

Patent Literature 1 discloses a manufacturing method of a shield member to allow reduction in height and a printed board on which the shield member is mounted. In Patent Literature 1, a frame unit 10 composed of a frame member 2 and a suction member 30 is used. When mounted on the printed board, the frame member 2 is attached in such a way that the suction member 30 is detachable with the frame-shaped frame member 2 (FIG. 33A). Then, as shown in FIG. 34, the top surface of the suction member 30 is sucked by a suction head 7, and the frame unit 10 is mounted onto a printed board 5 by the suction head 7. After that, the frame member 2 is soldered to the board. The frame member 2 is thereby physically and electrically connected to the printed board 5. After the soldering process, the suction member 30 is detached (FIG. 33B). Further, a cover member 4 is attached to the frame member 2 (FIG. 33C). A shield member for providing electromagnetic shielding is thereby made.

In this manner, the suction member 30 serving as a suction part is made detachable to be a separate part from the frame member 2. This eliminates the need for the frame member 2 to have a suction part, which allows the frame member 2 to have a reduced height. It is thereby possible to reduce the height of the shield structure.

Further, in Patent Literature 1, the top surface of the suction member 30 has a step 31 as shown in FIG. 35, and the step portion is sucked for mounting on the printed board. This allows further reduction in the height of the frame member 2. Specifically, the height of the frame member 2 can be set equal to the height of an electronic component 6 that is mounted inside the frame.

The suction member 30 is generally manufactured by molding a thin metal plate such as stainless steel or nickel silver into a predetermined shape by bending. A protrusion of the suction member 30 and a depression of the frame member 2 fit each other, so that the frame member 2 is grasped by the suction member 30. Specifically, the frame member 2 has a hole at a predetermined position on its side wall, and the suction member has a protrusion at a position corresponding to the hole on its side wall. By fitting them each other, the suction member is attached to the frame member. The strength of the fitting portion (the load for the suction member 30 to hold the frame member 2) largely depends on the elastic force of the side wall of the suction member 30. Because the material of the suction member 30 is metal, it does not easily come off.

### CITATION LIST

### Patent Literature

Japanese Unexamined Patent Application Publication No. 2008-34713

### SUMMARY OF INVENTION

### Technical Problem

However, the shield member disclosed in Patent Literature 1 has a problem that further reduction in height is difficult.

In the shield member of Patent Literature 1, further reduction in the thickness of a mounted component leads to further reduction in the thickness of the shield member with reduction in the thickness of a semiconductor component. Thus, the frame member is reduced in height with reduction in the thickness of a semiconductor component.

However, the wall surface of the frame member has the hole into which the protrusion of the suction member fits. There is thus a possibility that solder is sucked into the gap between the wall surface of the frame member and the wall surface of the suction member. In this case, the suction member cannot be easily detached in order to attach the shield member. Further, even if it is detached, solder is left, which hinders attachment of the shield member.

The present invention has been accomplished to solve the above problem and an exemplary object of the invention is thus to provide a frame member, a frame unit, a mounting board unit, and a manufacturing method thereof in which a shield member has a reduced height.

### Solution to Problem

In one exemplary aspect of the invention, a frame unit to be attached to a mounting board on which an electronic component is mounted includes a frame member having an opening where the electronic component is placed, a side wall to be connected to the mounting board, and a first protruding portion protruding inward or outward from the side wall, and a first member detachably attached to the frame member and having a second protruding portion protruding toward the frame member to fit with the first protruding portion.

In one exemplary aspect of the invention, a frame unit to be attached to a mounting board on which an electronic component is mounted includes a frame member having an opening where the electronic component is placed, a side wall to be connected to the mounting board, and a first protruding portion protruding inward or outward from the side wall, and a second member detachably attached to the frame member and having a holding part placed above the first protruding portion and a support part placed below the first protruding portion to grasp the first protruding portion.

In one exemplary aspect of the invention, a mounting board unit on which an electronic component is mounted includes a board, an electronic component mounted on the board, a frame member having a side wall surrounding the electronic component and a first protruding portion protruding inward or outward from the side wall and fit by a first member detachably attached to the frame member, and solder applied all around the frame member to connect the frame member to the board.

In one exemplary aspect of the invention, a manufacturing method of a mounting board unit on which an electronic component and a frame member surrounding the electronic component are mounted includes a step of preparing a frame member having a side wall to delimit an opening where the electronic component is placed and a first protruding portion protruding inward or outward from the side wall, a step of fixing a first member to the frame member by fitting the first member having a second protruding portion with the first protruding portion, a step of placing the frame member onto the board by sucking or grasping the first member using a suction mechanism or a grasping mechanism, a step of mounting the frame member on the board, and a step of detaching the first member from the frame member.

In one exemplary aspect of the invention, a manufacturing method of a mounting board unit on which an electronic component and a frame member surrounding the electronic component are mounted includes a step of preparing a frame member having a side wall to delimit an opening where the electronic component is placed and a first protruding portion protruding inward or outward from the side wall, a step of fixing a second member to the frame member by holding the first protruding portion between a holding part and a support part of the second member, a step of placing the frame member onto the board by sucking or grasping the second member using a suction mechanism or a grasping mechanism, a step of mounting the frame member on the board, and a step of detaching the second member from the frame member.

### Advantageous Effects of Invention

According to the exemplary aspect of the invention, it is possible to provide a frame member, a frame unit, a mounting board unit, and a manufacturing method thereof in which a shield member has a reduced height.

### BRIEF DESCRIPTION OF DRAWINGS

FIG. 1 is a perspective view showing a structure of a mounting board unit according to a first exemplary embodiment of the invention;

FIG. 2 is a development view showing a structure of a frame unit used in the mounting board unit;

FIG. 3 is a perspective view showing a structure of a first member used in the frame unit according to the first exemplary embodiment;

FIG. 4 is a side cross-sectional view showing the attachment structure of the first member and a frame member;

FIG. 5 is a top view showing the structure of the mounting board unit according to the first exemplary embodiment of the invention;

FIG. 6 is a side view showing the structure of the mounting board unit according to the first exemplary embodiment of the invention;

FIG. 7 is a side view showing the structure of the mounting board unit according to the first exemplary embodiment of the invention;

FIG. 8 is a side cross-sectional view showing the structure of the mounting board unit according to the first exemplary embodiment of the invention;

FIG. 9 is a side cross-sectional view showing in a larger scale the mounted state of the frame unit according to the first exemplary embodiment of the invention;

FIG. 10 is a side cross-sectional view showing the frame unit according to the first exemplary embodiment of the invention;

FIG. 11 is a perspective view showing a structure of the mounting board unit in which a shield cover is attached;

FIG. 12 is a top view showing the structure of the mounting board unit in which the shield cover is attached;

FIG. 13 is a side view showing the structure of the mounting board unit in which the shield cover is attached;

FIG. 14 is a side cross-sectional view showing the structure of the mounting board unit in which the shield cover is attached;

FIG. 15 is a perspective view showing a structure of a mounting board unit according to a second exemplary embodiment;

FIG. 16 is a development view showing a structure of a frame unit used in the mounting board unit;

FIG. 17 is a perspective view showing a structure of a second member used in the frame unit according to the second exemplary embodiment;

FIG. 18 is a top view showing the structure of the mounting board unit according to the second exemplary embodiment of the invention;

FIG. 19 is a side view showing the structure of the mounting board unit according to the second exemplary embodiment of the invention;

FIG. 20 is a side cross-sectional view showing the structure of the mounting board unit according to the second exemplary embodiment of the invention;

FIG. 21 is a side cross-sectional view partly showing an aspect of a mounting board unit according to a third exemplary embodiment of the invention;

FIG. 22 is a perspective view partly showing an aspect of the mounting board unit according to the third exemplary embodiment of the invention;

FIG. 23A is a side cross-sectional view showing an alternative example of the attachment state of the frame unit according to the invention;

FIG. 23B is a side cross-sectional view showing an alternative example of the attachment state of the frame unit according to the invention;

FIG. 23C is a side cross-sectional view showing an alternative example of the attachment state of the frame unit according to the invention;

FIG. 23D is a side cross-sectional view showing an alternative example of the attachment state of the frame unit according to the invention;

FIG. 23E is a side cross-sectional view showing an alternative example of the attachment state of the frame unit according to the invention;

FIG. 23F is a side cross-sectional view showing an alternative example of the attachment state of the frame unit according to the invention;

FIG. 24A is a side view showing another structure of the frame unit according to the invention;

FIG. 24B is a side view showing another structure of the frame unit according to the invention;

FIG. 25 is a top view showing another aspect of the first member used in the mounting board unit according to the invention;

FIG. 26 is a side view showing another aspect of the first member used in the mounting board unit according to the invention;

FIG. 27 is an exploded perspective view showing a structure of a mounting board unit according to a first alternative example;

FIG. 28 is a perspective view showing the structure of the mounting board unit according to the first alternative example;

FIG. 29 is a side cross-sectional view showing the structure of the mounting board unit according to the first alternative example;

FIG. 30 is an exploded perspective view showing a structure of a mounting board unit according to a second alternative example;

FIG. 31 is a perspective view showing the structure of the mounting board unit according to the second alternative example;

FIG. 32 is a side cross-sectional view showing the structure of the mounting board unit according to the second alternative example;

FIG. 33A is a perspective view showing a structure of a mounting board in Patent Literature 1;

FIG. 33B is a perspective view showing the structure of the mounting board in Patent Literature 1;

FIG. 33C is a perspective view showing the structure of the mounting board in Patent Literature 1;

FIG. 34 is a side cross-sectional view showing a structure of a mounting frame unit in Patent Literature 1; and

FIG. 35 is a view showing another structure of the mounting frame unit in Patent Literature 1.

### DESCRIPTION OF EMBODIMENTS

Exemplary embodiments of the present invention are described hereinbelow. It should noted that the size and proportion of each component in the following drawings are just for the sake of simplicity and not always the same as the actual size and proportion.

### First Exemplary Embodiment

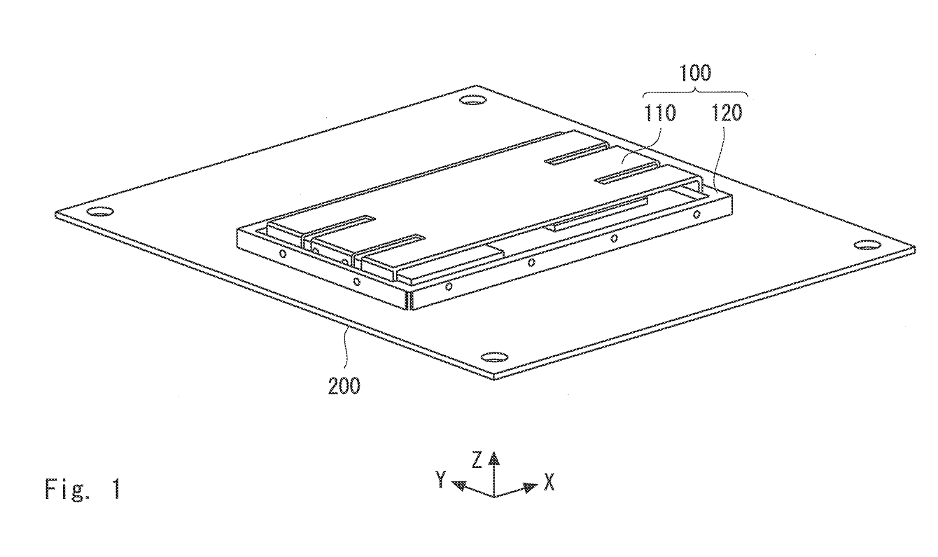

FIG. 1 shows an outline view of a mounting board unit according to an exemplary embodiment of the invention. FIG. 1 is a perspective view showing a mounting board unit that is used in portable equipment such as a mobile telephone, for example. Note that a structure in which a frame member 120 is attached to a mounting board on which an electronic component is mounted is referred to as a mounting board unit. In the following description, a three-dimensional orthogonal coordinates system is used to simplify the explanation. As shown in FIG. 1, the direction of the thickness of a board 200 is Z direction, and the directions parallel to the end sides of the board 200 are X and Y directions. In the following description, the Z direction is referred to as a lengthwise direction (height direction), and the X and Y directions are referred to as crosswise directions.

The mounting board unit includes a board 200 and a frame unit 100. The board 200 is a printed wiring board, for example, and wiring that is connected to an electronic component or the like is formed thereon. The frame unit 100 includes a frame member 120 and a first member 110. The frame unit 100 is a temporarily assembled component to mount a shield structure onto an electronic board. For example, the frame member 120 of the frame unit 100 is mounted on the board 200. Further, the first member 110 is attached to the frame member 120. An electronic component (not shown in FIG. 1) is placed inside the frame unit 100. Note that the frame member 120 is formed in the shape of a frame enclosing the electronic component. At the time of actual use of the electronic component, the first member 110 is detached from the frame member 120, and a shield cover is placed thereon. Thus, the first member 110 is not used at the time of actual use of the electronic component.

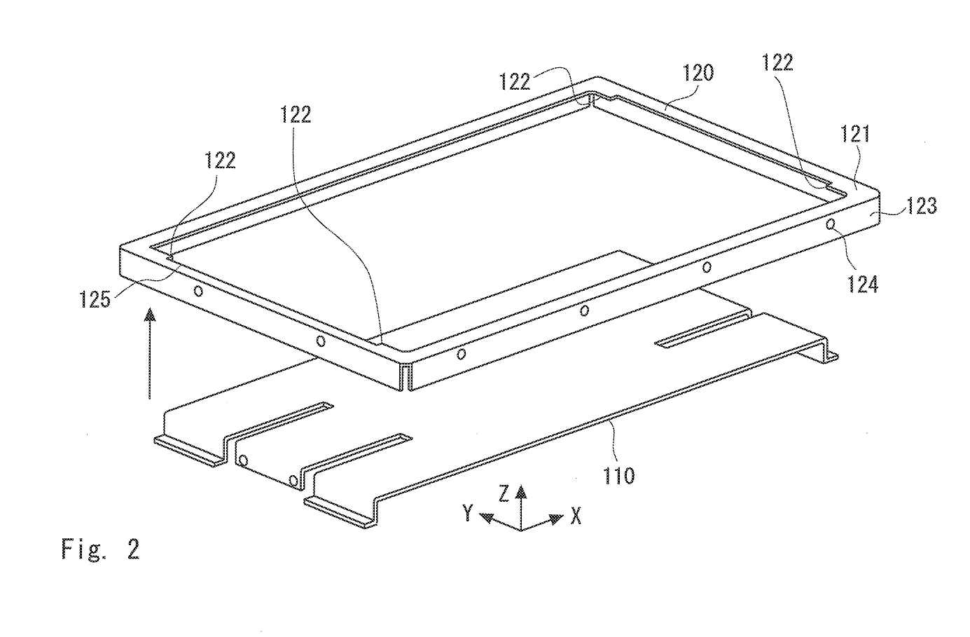

The structure of the frame unit 100 is described hereinafter with reference to FIG. 2. FIG. 2 is an exploded perspective view showing the structure of the frame unit. As shown in FIG. 2, the frame member 120 is formed in the shape of a frame. Each edge of the frame-shaped frame member 120 is arranged in parallel with the X direction or the Y direction. The frame member 120 has a first protrusion 121, a step 122, a side wall 123, a second protrusion 124, and an opening 125.

The frame member 120 has the opening 125 that makes the electronic component visible when the first member 110 is detached. The side wall 123 is placed to delimit the opening 125. The opening 125 is located inside the side wall 123. The side wall 123 serves as a frame that is located outside the electronic component. Two side walls 123 along the X direction and two side walls 123 along the Y direction are joined to form the frame member 120 having a rectangular frame shape. The height of the side wall 123 corresponds to the height of the mounted electronic component.

The second protrusion 124 is formed on the outside of the side wall 123. The second protrusion 124 is to attach a shield cover, which is described later. The second protrusion 124 is placed on the side face of the side wall 123, for example. Four second protrusions 124 are formed on the part of the side wall 123 along the X direction, and two second protrusions 124 are formed on the part of the side wall 123 along the Y direction. The eight second protrusions 124 protrude outward from the side wall 123. The first protrusion 121 is placed on the upper side of the side wall 123. The first protrusion 121 extends inward from the side wall 123. In other words, the first protrusion 121 protrudes horizontally inward from the top face of the side wall 123. The first protrusion 121 is a protruding portion that protrudes from the side wall. Specifically, on the side wall 123 along the X direction, the first protrusion 121 protrudes in the Y direction, and, on the side wall 123 along the Y direction, the first protrusion 121 protrudes in the X direction.

The first member 110 is placed inside the frame-shaped frame member 120. Specifically, the first member 110 is inserted into the opening 125 of the frame member 120. Then, the first member 110 is placed against the first protrusion 121 of the frame member 120. Further, the first protrusion 121 has the step 122. The step 122 is described later.

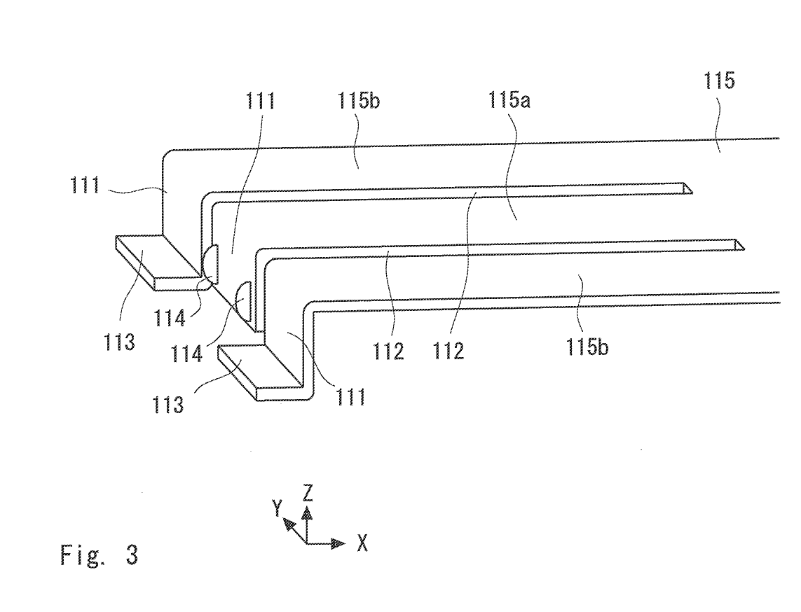

The structure of the first member 110 is described in detail with reference to FIG. 3. FIG. 3 is a perspective view showing the structure of the first member 110, which shows the structure of one end of the first member 110 in an enlarged scale. Note that the structure of the other end of the first member 110 is the same as the structure of that end. The first member 110 has a symmetric structure with the Y axis being the axis of symmetry. The first member 110 is made up of a center area serving as a suction area, and an end area shown in FIG. 3. Specifically, an area inside the position at which the end of a slit 112 is located in the X direction is the center area, and an area outside that position is the end area. The first member 110 has a bent part 111, a slit 112, a support part 113, a third protrusion 114, and a top surface 115.

The top surface 115 has the slit 112 along the X direction. Two slits 112 are formed in the end area of the top surface 115. The two slits 112 are arranged in parallel. The end area of the top surface 115 is divided into three sections by the two slits 112. The three sections are referred to as a mid section 115a and both end sections 115b as shown in FIG. 3. The mid section 115a is located between the two slits 112, and the both end sections 115b are located on respective outer sides of the two slits 112. In other words, the mid section 115a is located between the both end sections 115b in the Y direction. The mid section 115a is arranged in parallel with the both end sections 115b. When viewed from above, the mid section 115a and both end sections 115b are rectangles of substantially the same size.

The width of the slit 112 is smaller than the width of the mid section 115a and the both end sections 115b. For example, the width of the slit 112 is 1.5 mm, and the width of the mid section 115a and the both end sections 115b is 4 mm. The slit 112 has a long linear shape along the X direction when viewed from above. For example, the length of the slit 112 is 10 mm, and the whole length of the first member 110 is 40 mm along the long side and 20 mm along the short side.

The top surface 115 is placed substantially in parallel with the X-Y plane and laid face-to-face with the board 200. Thus, the top surface 115 is placed in parallel with the board 200 above the board 200 shown in FIG. 1. Note that, because there is a manufacturing error and assembly error in practice, the top surface 115 is substantially in parallel with the board 200. In the case of moving the frame unit 100 onto the board 200, the top surface 115 is sucked by a suction pad or the like. The first member 110 to which the frame member 120 is attached is thereby sucked so that the frame unit 100 can be carried.

The bent part 111 is formed at the end of the top surface 115. Specifically, the slit 112 is cut in a thin metal plate to divide the end area into three sections (the mid section 115a and the both end sections 115b). At some midpoint of the end area (slit area) divided into three sections, the thin metal plate is bent to form the bent part 111.

The both end sections 115b have the bent part 111 along the Z-Y plane and the support part 113 along the X-Y plane. The support part 113 is at the end of the bent part 111. The support part 113 is placed substantially in parallel with the X-Y plane. The support part 113 and the top surface 115 are substantially in parallel with each other. The support part 113 supports the frame member 120. The support part 113 protrudes outward in the X direction from the bent part 111. The bent part 111 of the mid section 115a has two third protrusions 114. Each of the third protrusions 114 protrudes outward in the X direction from the bent part 111 that is substantially in parallel with the Z-Y plane and arranged in the direction (Y direction) parallel with the top surface of the support part 113.

The support part 113 is placed close to the board 200 than the third protrusion 114 is. In this manner, the support part 113 and the third protrusion 114 are placed at different positions in the Y direction. The first protrusion 121 is grasped by the support part 113 and the third protrusion 114, so that the first member 110 is attached to the frame member 120.

Note that the first member 110 may be manufactured by forming a thin metal plate such as stainless steel or nickel silver into a predetermined shape by bending. For example, the bent part 111 may be formed by bending the thin metal plate at 90 degrees. The first member 110 is a sheet metal part having spring properties.

The slit 112 allows easy deformation of the first member 110. Because the slit 112 exists between the both end sections 115b having the support part 113 and the mid section 115a having the third protrusion 114, the mid section 115a and the both end sections 115b can slightly swing independently of each other. At the time of fitting the first member 110 into the frame member 120 from below, the mid section 115a is flexed and pressed thereinto. Further, at the time of detaching the first member 110 upward from the frame member 120, the both end sections 115b are warped. Thus, the top surface 115 is easily deformed because of having the slit 112. The first member 110 can be thereby attached to and detached from the frame member 120. Note that the orientation of the slit 112 is not particularly limited. Further, because of the structure that holds the first protrusion 121, it possible to prevent the transverse load from resting on the side wall 123 at the time of detaching the first member 110. This prevents deformation of the first member 110.

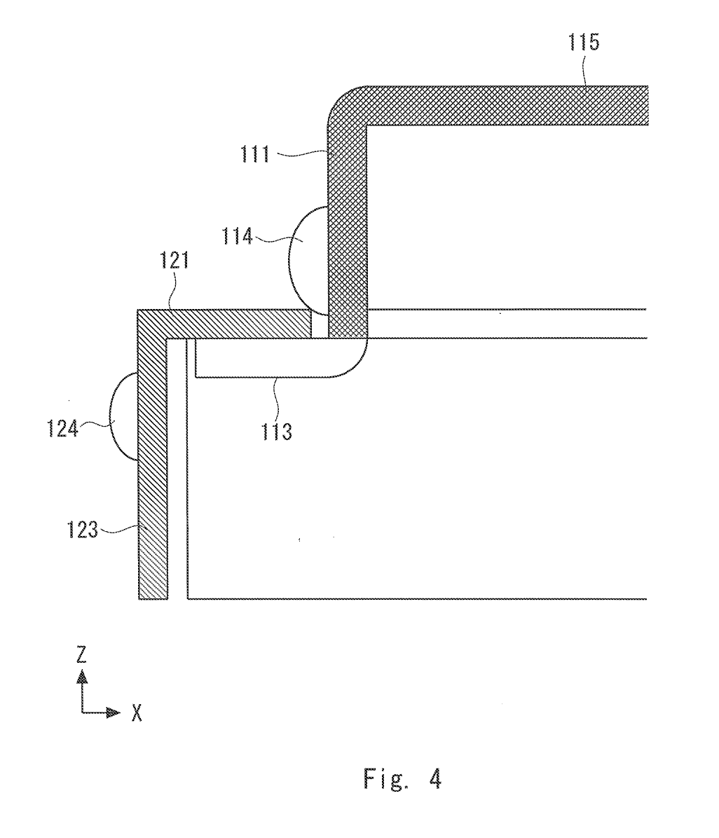

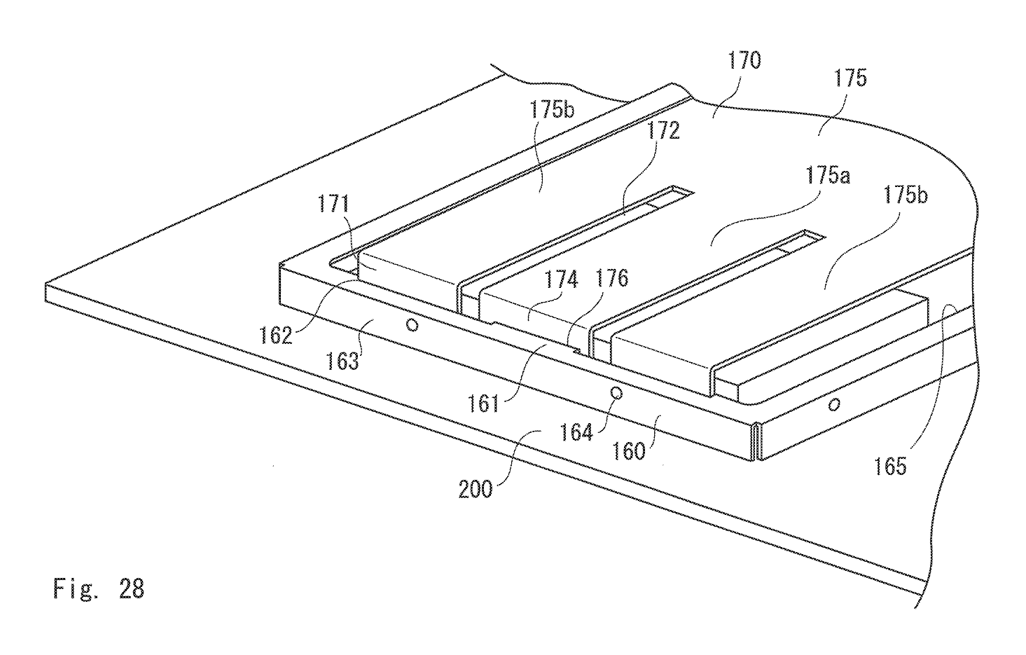

The structure to attach the frame member 120 to the first member 110 is described hereinafter with reference to FIG. 4. FIG. 4 is a side cross-sectional view showing the attachment structure, which shows the structure in which the end portion of the frame member 120 fits with the mid section 115a and the both end sections 115b in an enlarged scale. As shown in FIG. 4, the undersurface of the first protrusion 121 is in contact or close proximity with the upper surface of the support part 113. Further, the upper surface of the first protrusion 121 is in contact or close proximity with the third protrusion 114. In other words, the support part 113 and the third protrusion 114 are placed in contact with the first protrusion 121 or with a small gap therebetween. In this manner, the first protrusion 121 is vertically interposed between the third protrusion 114 and the support part 113. The first member 110 is thereby fixed to the frame member 120. Stated differently, the structure to fit with the first protrusion 121 is made on the side surface of the first member 110. The first member 110 and the frame member 120 are thereby integrated as the frame unit 100. When carrying the frame unit 100, the first member 110 is sucked by a suction pad (which is the same as the one shown in FIG. 28) or the like. The frame unit 100 can be thereby carried onto the board 200. Further, because the first protrusion 121 is held in this structure, the frame member 120 is not distorted by the grasping load that occurs when the first member 110 grasps the first protrusion 121. Because the first member 110 does not directly grasp the side wall 123, the deformation of the side wall 123 can be avoided.

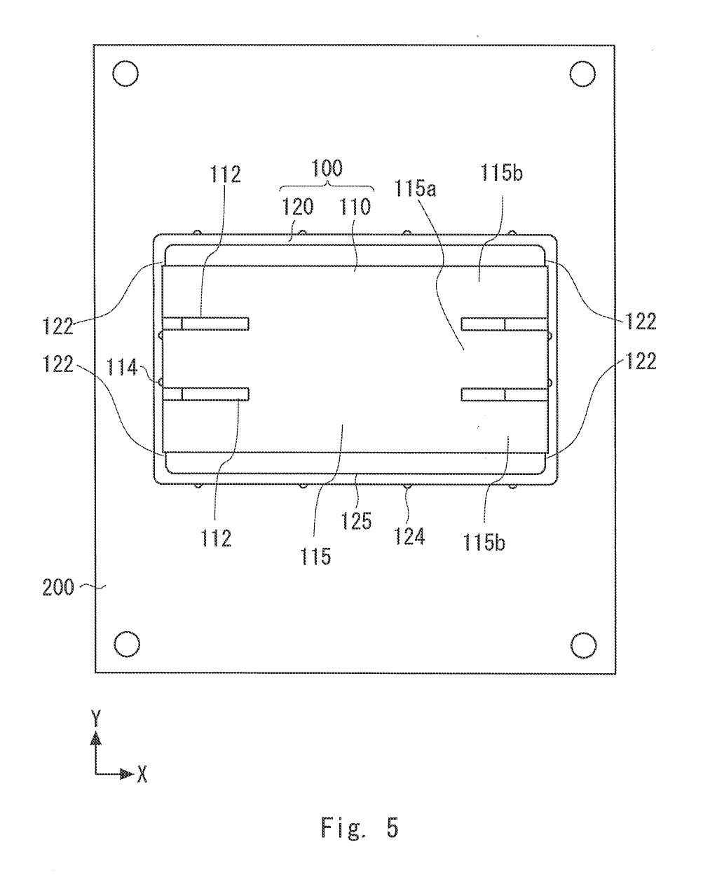

The function of the step 122 of the frame member 120 is described hereinafter with reference to FIG. 5. FIG. 5 is a top view showing the structure of the mounting board unit. In the X direction, the first member 110 is placed from one end to the other end of the frame member 120. The first member 110 fits with the first protrusion 121 of two side walls (side walls along the Y direction) excluding two opposed side walls (side walls along the X direction) of the frame member 120. Thus, the two side walls along the X direction of the frame member 120 are not fit by the first member 110 and left free. As shown in FIG. 5, the width of the first protrusion 121 changes at some position, and the position at which the width changes is the step 122. In both sides of the longitudinal direction of the first member 110, the step 122 projects toward the opening 125. The step 122 restricts the position of the first member 110 in the Y direction. The first member 110 is placed in the part where the width of the first protrusion 121 decreases in the X direction by the step 122. Then, the part where the width of the first protrusion 121 increases in the X direction by the step 122 comes into contact or close proximity with the first member 110, so that the first member 110 is set in position with respect to the frame member 120 in the Y direction. Because the first member 110 is held by the step 122 on both sides, the first member 110 can be fixed tightly. In this manner, the first member 110 fits into the frame member 120 and is thereby held fast. It is thereby possible to prevent lateral displacement of the first member 110.

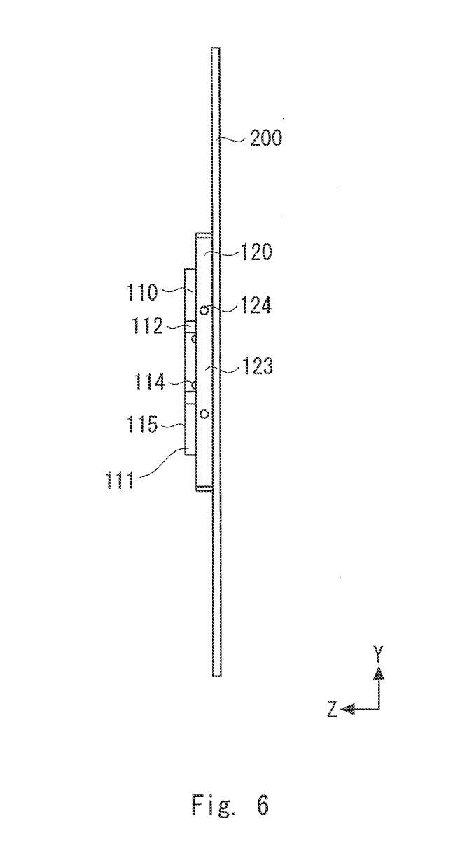

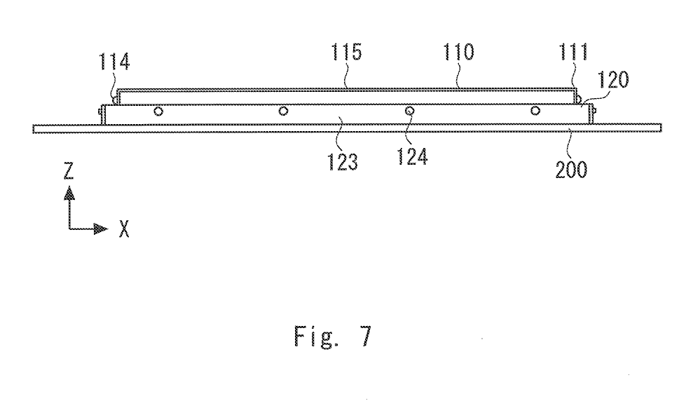

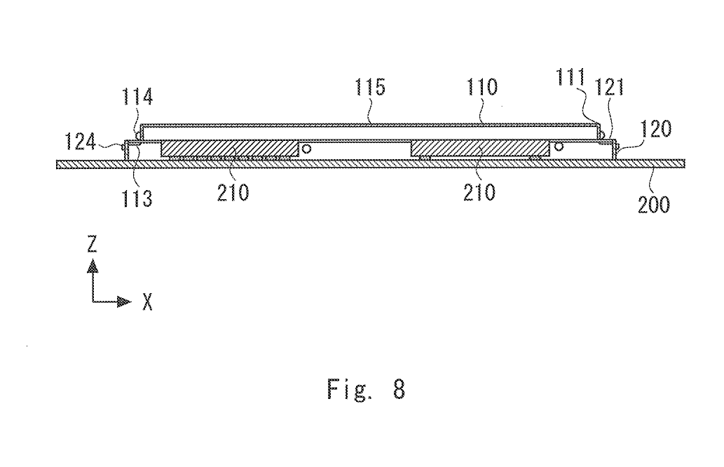

Further, because the first member 110 has the bent part 111, the height of the first member 110 changes. Therefore, as shown in FIGS. 6 and 7, the top surface 115 of the first member 110 projects from the upper surface of the frame member 120 in the Z direction. Specifically, with the bent part 111, the height of the first member 110 from the board 200 changes and becomes higher than the frame member 120. Then, an electronic component 210 is mounted on the position where the first member 110 is heightened as shown in FIG. 8. Specifically, the electronic component 210 such as IC is mounted on the position where it is visible through the opening 125. Further, a plurality of electronic components 210 having different functions may be mounted within the frame member 120.

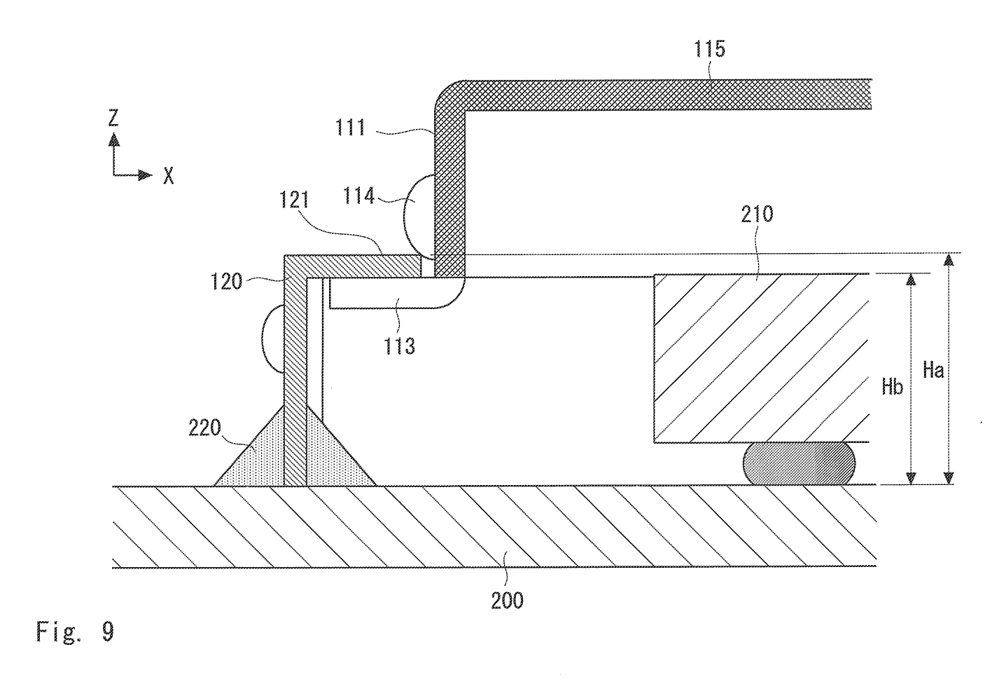

In this structure, the space to mount the electronic component 210 can be heightened. It is thereby possible to reduce the height of the frame member 120 compared to the structure not using the frame member and the first member according to the exemplary embodiment. The reason for this is described hereinafter with reference to FIGS. 9 and 10. FIG. 9 is a side cross-sectional view showing the state where the frame member 120 is soldered. FIG. 10 is a side cross-sectional view showing the state where frame unit is soldered onto the mounting board without using the frame member and the first member according to the exemplary embodiment.

As shown in FIG. 9, solder 220 is provided at the lower end of the frame member 120. The frame member 120 is thus fixed to the board 200 by the solder 220. The frame member 2 in Patent Literature 1 is also fixed to the board 200 by the solder 220 (FIG. 10). The frame member 2 in Patent Literature 1 has a hole 23. The suction member 3 has a protrusion 33 that fits into the hole 23. Further, the hole 23 is made in the side wall of the frame member 2. Then, the protrusion 33 is inserted into the hole 23, so that the frame member 2 is fixed to the suction member 3.

The solder 220 before reflow after mounting is wet and spread over the surface when the solder is activated by the reflow process. In this case, solder 230 crawls up as shown in FIG. 10, causing the frame member 2 and the suction member 30 to be fixed. In this manner, the solder 230 is wetted and spread to the space between the frame member 2 and the suction member 30. Then, the suction member 30 is fixed to the frame member 2, which makes the suction member 30 undetachable. This makes it impossible to detach the suction member 30 from the frame member 2 and place the shield cover.

Thus, the structure shown in FIG. 10 raises the need to design the frame member 2 to have an increased height so that the solder 220 does not soak up. It is required to increase the height of the frame member 2 regardless of the height of the electronic component 210. Specifically, it is necessary to keep the protrusion 33 away from the board 200 so that the frame member 2 and the suction member 30 are not connected at the position of the protrusion 33 even when the solder 220 is wet and spread out. It is thereby necessary to design the frame member 2 to have a certain height, which makes it difficult to reduce the height.

On the other hand, in the frame unit according to this exemplary embodiment, the first member 110 is attached to the first protrusion 121 that is located at the top end of the frame member 120 as shown in FIG. 9. Specifically, the first protrusion 121 is held between the support part 113 and the third protrusion 114 of the first member 110. Thus, a height Hb of an electronic component can be lower than a height Ha of a shield frame by the dimensional tolerance (about 0.1 mm in general) before and after mounting. In this way, the electronic component 220 and the shield cover do not interfere with each other when the shield cover is finally assembled. In this exemplary embodiment, because the first member 110 does not exist near the solder 220 as shown in FIG. 9, it is possible to prevent the first member 110 and the frame member 120 from being connected. This allows further reduction in height. Further, in this structure, the first protrusion 121 protruding from the side wall 123 is held by the first member 110. This reduces a force applied to the side wall 123 from the first member 110. It is thereby possible to reduce the transverse load on the side wall 123 and prevent deformation of the frame member 120.

A manufacturing method for the frame unit and the mounting board unit according to the exemplary embodiment is described hereinbelow. First, the frame member 120 and the first member 110 having the above-described structure are prepared. Then, the first member 110 is fixed to the frame member 120. Specifically, the first member 110 is inserted into the opening 125 of the frame member 120 from below. The first protrusion 121 of the frame member 120 is thereby held between the third protrusion 114 and the support part 113 of the first member 110. The support part 113 comes into contact or close proximity with the under surface of the first protrusion 121, and the third protrusion 114 comes into contact or close proximity with the top surface of the first protrusion 121. The first member 110 thereby grasps the frame member 120 to allow carriage.

Solder is applied onto the board 200, and the electronic component 210 and the frame member 120 are attached thereto. For example, precision solder printing using a metal mask is performed on the board 200. The solder 220 is provided at the position to which the electronic component 210 and the frame unit are attached. Note that the electronic component 210 may be attached by a method other than soldering, such as wire bonding, for example. Then, the electronic component 210 is mounted on the board 200. Further, the frame unit 100 is mounted thereon. The frame unit 100 can be carried by a general-purpose mounting machine. Specifically, mounting using pick-and-place suction is possible. There is thus no need to use a special device, jig or the like for carriage of the frame unit. The manufacturing cost can be thereby reduced. For example, the shared use of a mounting machine for the frame member 120 and a mounting machine for the electronic component is possible.

In this process, the first member 110 is sucked by a suction nozzle that is used at the time of pick-and-place by a mounting machine. Thus, the mid section of the first member 110 needs to have a structure to withstand the suction. The suction part of the first member 110 should not have a cut or fracture. By using the first member 110 for carriage, reduction in height can be achieved. As a matter of course, the frame unit 100 may be raised using a mechanism other than a suction mechanism such as a suction pad. For example, the frame unit 100 may be grasped by a grasping mechanism that grasps the first member 110.

On the board 200 on which the electronic component 210 and the frame unit 100 are mounted, the reflow process is performed. The reflow process makes melting junction of solder. The solder is thereby heated to a melting temperature and wet-spread. When the temperature drops, the board 200 and the electronic component 210 are mounted through the solder. Further, the board 200 and the frame member 120 are mounted through the solder. When soldering is done by the reflow process, the electronic component 210 and the frame unit 100 are fixed to the board 200. At this time, the frame member 120 of the frame unit 100 is soldered to the mounting board and thus firmly fixed. In this state, the first member 110 is removed upward by elastic deformation or removed by cutting off a part of the first member 110. Further, even when the solder is wet-spread, the frame member 120 and the first member 110 are not connected. The first member 110 can be thereby easily detached, which increases productivity. Note that the first member 110 preferably has an elastically deformable structure. This eliminates the need to cut off the first member 110 and allows reuse of the first member 110.

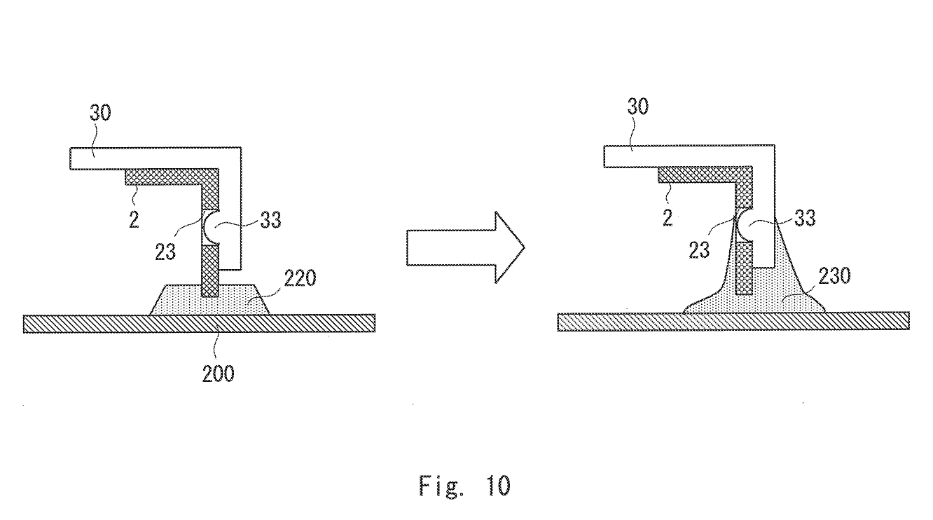

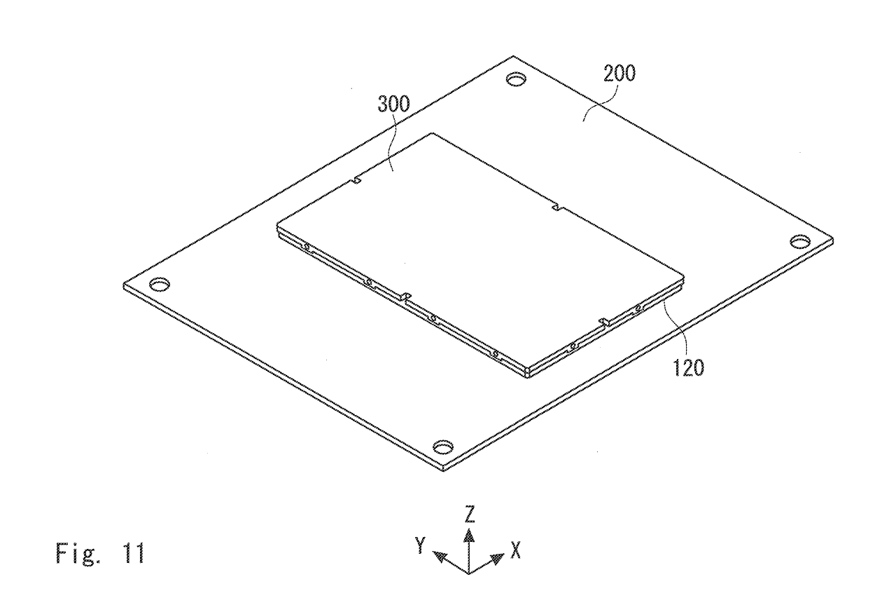

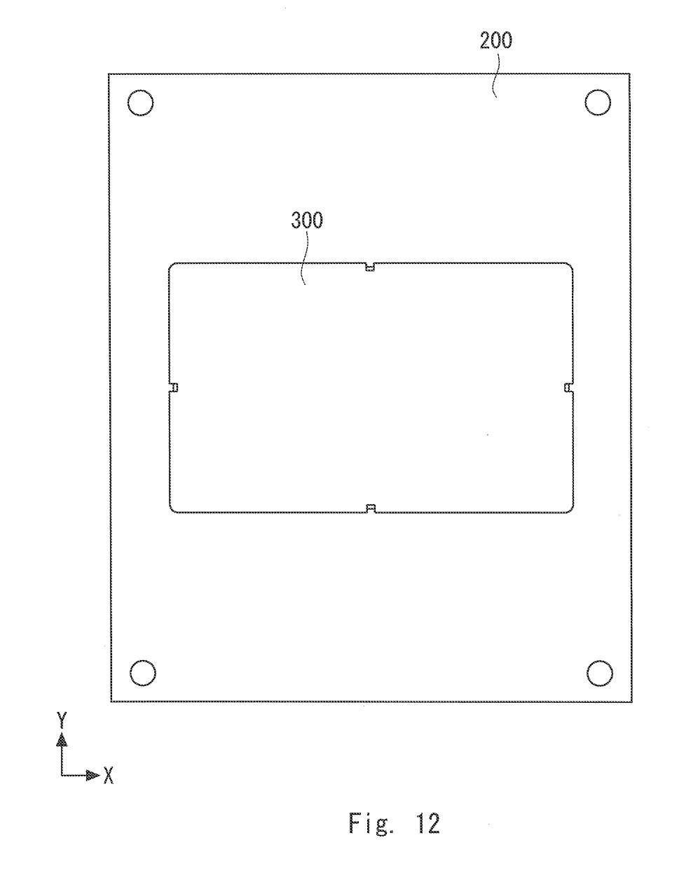

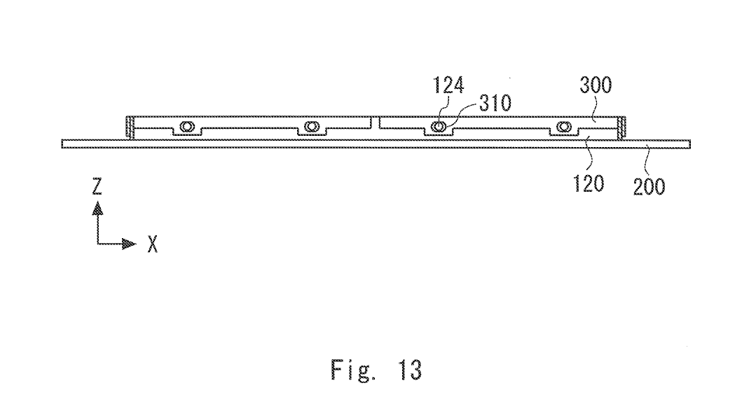

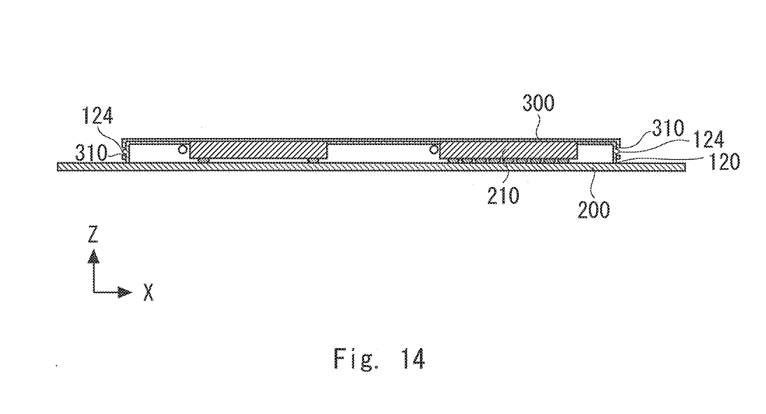

A shied cover is attached to the frame member 120 from which the first member 110 is detached. The opening of the frame member 120 is thereby covered with a shield cover 300 as shown in FIGS. 11 to 14. The shield cover 300 completely covers the opening 125 of the frame member 12 as shown in FIG. 12. The shield cover 300 is made of a thin metal plate or the like. To fix the shield cover 300, the second protrusion 124 of the frame member 120 is fit into a hole 310 of the shield cover, for example. Specifically, the second protrusion 124 is inserted into the hole 310 of the shield cover 300 as shown in FIG. 14. The frame member 120 and the shield cover 300 are thereby electrically and mechanically connected to form a shield structure. Further, the fitting structure of the frame member 120 and the shield cover 300 may be opposite. Specifically, the frame member 120 may have a depression such as a through hole, and the shield cover may have a protrusion at the position corresponding to the depression. This structure also allows the shield cover 300 to be mounted.

Note that solder may be provided all around the frame member 120. Specifically, the solder 220 is applied to the entire periphery of the frame member 120 with no space, and the frame member 120 is connected to the board 200 by the solder 220. The shield performance is thereby improved. In this exemplary embodiment, the first member 110 and the frame member 120 are fixed with the first protrusion 121 interposed therebetween. Thus, even when solder crawls up to the height of the second protrusion 124, the frame member 120 and the first member 110 are not connected. An all-round solder structure is thereby made. In the case of performing all-round soldering, it is designed so that the solder does not soak up to the third protrusion 114 to fit into the hole 310 of the shield cover 300.

Note that, although the structure in which two third protrusions 114 are placed on the mid section 115a is described above, the number of third protrusions 114 is not particularly limited.

### Second Exemplary Embodiment

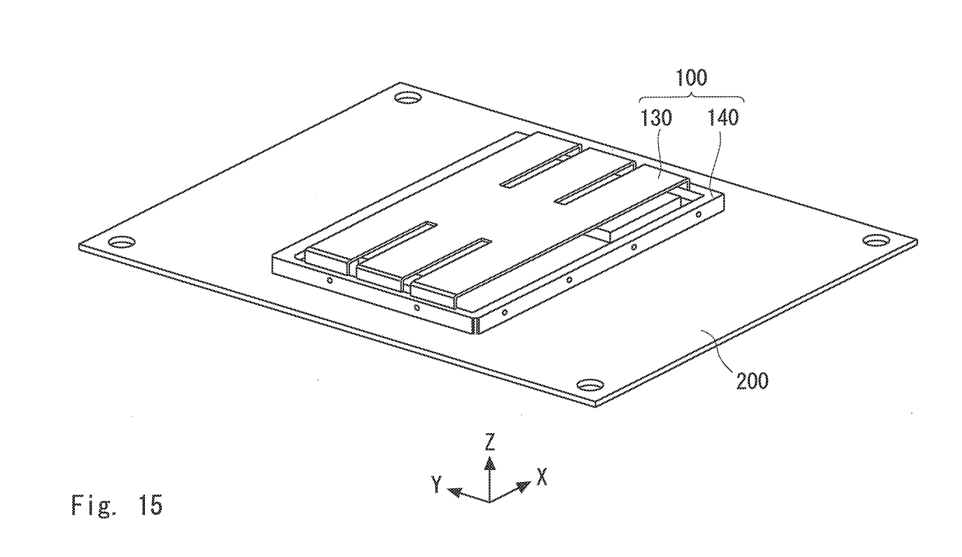

A frame unit 100 and a mounting board unit according to a second exemplary embodiment of the invention are described hereinafter with reference to FIG. 15. FIG. 15 is a perspective view showing the state where the frame unit 100 is mounted on the board 200. FIG. 15 shows the mounting board unit that includes the frame unit 100 and the board 200. Note that the basic structure and manufacturing method of the frame unit 100 and the mounting board unit according to this exemplary embodiment are the same as those of the first exemplary embodiment, and redundant description thereof is omitted as appropriate. In this exemplary embodiment, a mechanism to fix a second member 130 to a frame member 140 is different from that of the first exemplary embodiment. Note that the second member 130 is a component corresponding to the first member 110 of the first exemplary embodiment. The second member 130 is grasped or sucked by a grasping mechanism or a suction mechanism.

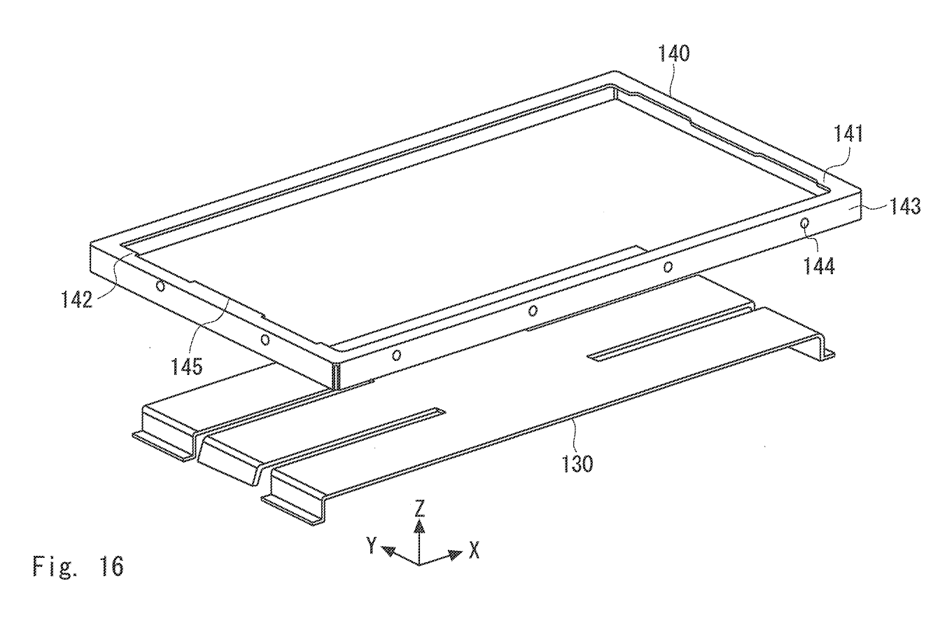

As shown in FIG. 15, the frame unit 100 is mounted on the board 200. The frame unit 100 includes the frame member 140 and the second member 130 just like in the first exemplary embodiment. The frame unit 100 has the structure shown in FIG. 16. The frame member 140 has substantially the same structure as the frame member 120 described in the first exemplary embodiment. Thus, a first protrusion 141, a step 142, a side wall 143, a second protrusion 144, and an opening 145 of the frame member 140 correspond to the first protrusion 121, the step 122, the side wall 123, the second protrusion 124, and the opening 125 of the frame member 120, respectively.

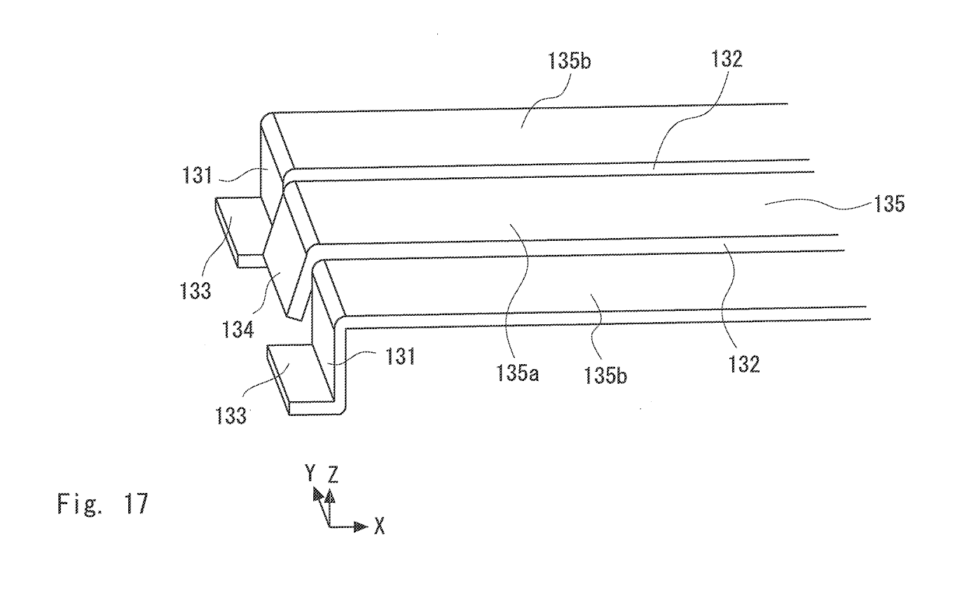

The structure of the second member 130 is as shown in FIG. 17. In the second member 130 according to this exemplary embodiment, a holding part 134 is formed instead of the third protrusion 114 described in the first exemplary embodiment. Specifically, the holding part 134 comes into contact or close proximity with the upper surface of the first protrusion 141, and a support part 133 comes into contact or close proximity with the under surface of the first protrusion 141. In other words, the holding part 134 holds down the first protrusion 141, and the support part 133 holds up the first protrusion 141, and thereby the holding part 134 and the support part 133 grasp the first protrusion 141. The second member 130 is thereby fixed to the frame member 140. This ensures firm grasping and reduces the possibility of accidental detachment during carriage or component mounting. The state where the frame unit 100 is connected to the board 200 is as shown in FIG. 18.

The holding part 134 is a side wall part that is placed at one end of a mid section 135a and extends from a top surface 135 to become wider toward the board 200. This allows the first protrusion 141 to be held down tightly.

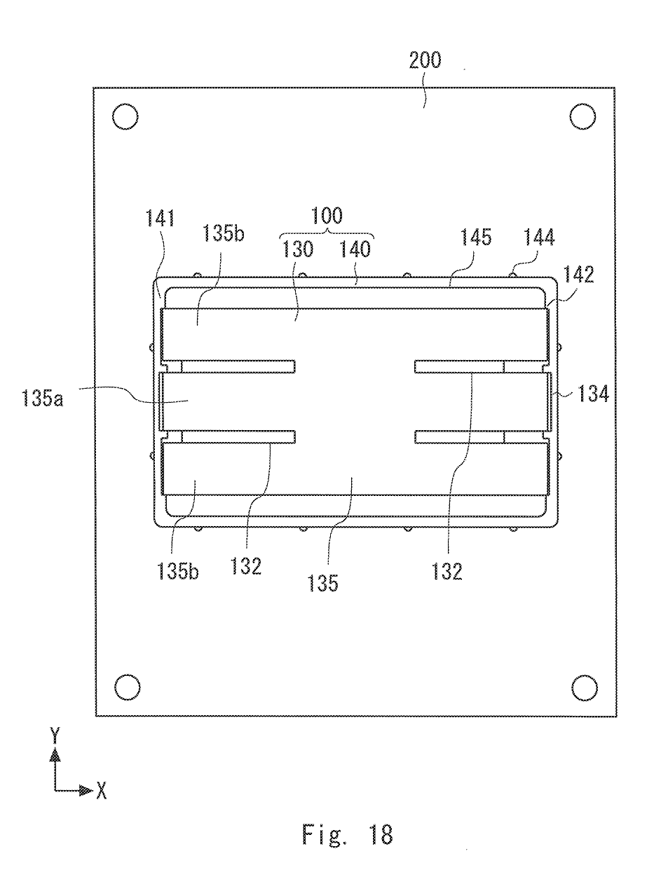

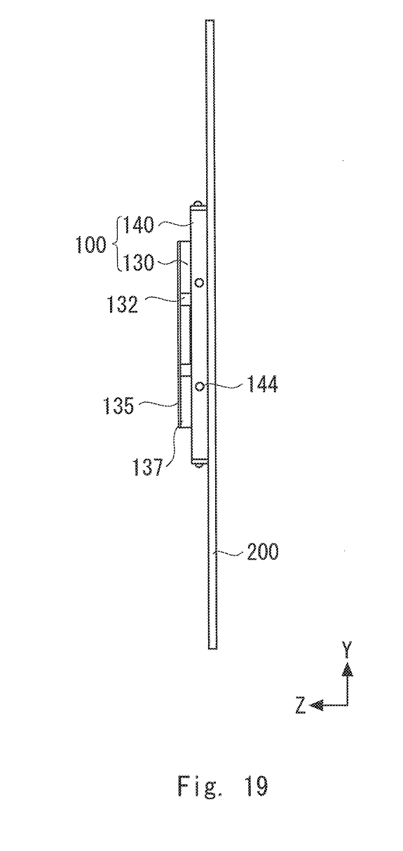

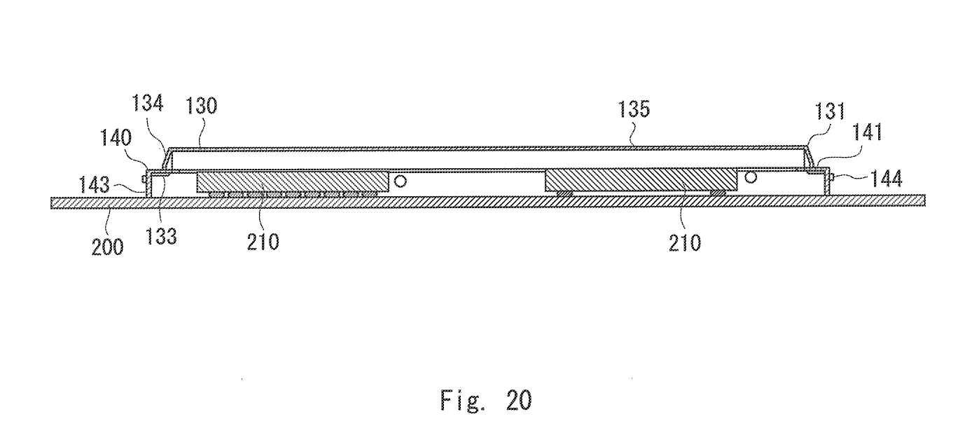

In this structure also, the frame unit 100 can be configured in the same manner as in the first exemplary embodiment. Thus, the same effects as in the first exemplary embodiment can be obtained. Specifically, as shown in FIG. 19, a top surface 135 projects upward from the frame member 140. The position where the electronic component 210 is placed can be thereby heightened as shown in FIG. 20. It is thereby possible to reduce the height of the frame member 140 compared to the structure not using the frame member and the first member according to the exemplary embodiment.

As described in the first and second exemplary embodiments, the first member or the second member grasps the first protrusion on the upper surface of the frame member by holding it from above and below. The first member or the second member is attached to the frame member at least before mounting and is detachable after mounting. This allows further reduction in height.

The first member or the second member is attached to the top surface of the frame member just after manufacturing the frame member or before mounting the frame member. The frame unit is thereby formed. The frame unit is mounted, together with another electronic component such as a semiconductor component, onto the board on which solder printing is done using an automatic mounting machine. Soldering is then performed by the reflow process. At the time of reflow soldering, the first member or the second member does not come into close proximity with the soldering part of the frame member. It is thereby possible to prevent the solder from crawling up. This allows the height of the frame member to be low. After mounting, the first member or the second member that is no longer needed may be detached by deformation or cutoff.

In the first and second exemplary embodiment, because the first member or the second member holds the upper surface part (the first protrusion) of the frame member from above and below, the first member or the second member does not come into close proximity with the soldering part of the frame member. It is thereby possible to prevent the crawling-up of solder. As a result, it is possible to reduce the height of the frame member to be thinner, thereby allowing the mounting board to be thinner. Further, the frame member and the first member or the second member are not connected even when solder is provided in the part where the protrusion of the frame member is formed. It is thereby possible to form the solder all around the frame member, thereby improving the shield performance. Note that a manufacturing method of the mounting board unit according to this exemplary embodiment is the same as that described in the first exemplary embodiment, and redundant description thereof is omitted.

### Third Exemplary Embodiment

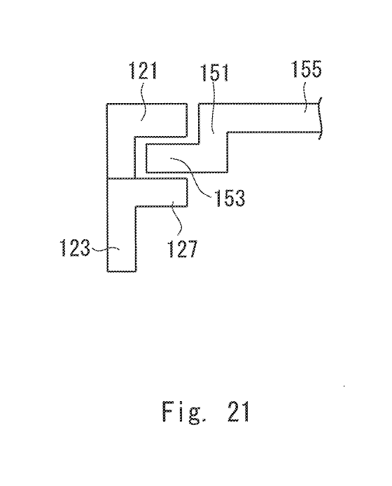

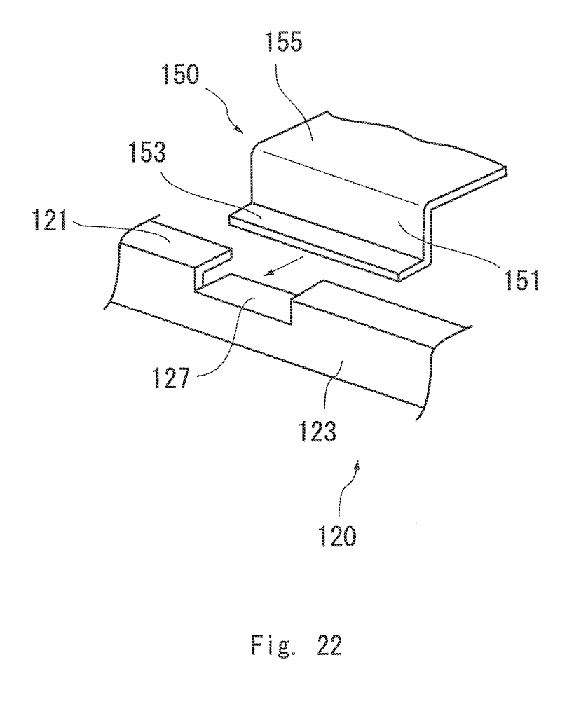

The structure in which the first protrusion 121 is held between the support part 113 and the third protrusion 114 and the structure in which the first protrusion 141 is held between the support part 133 and the holding part 134 are described in the first and second exemplary embodiments, respectively. However, the frame member may hold the other member instead. This structure is described hereinafter with reference to FIGS. 21 and 22.

A member that is grasped or sucked by a grasping mechanism or a suction mechanism is referred to as a third member 150. The third member 150 thus corresponds to the first member 110 and the second member 130. The third member 150 has a top surface 155, a support part 153, and a bent part 151. The basic structures of those components are the same as those of the top surface 115, the support part 113 and the bent part 111 of the first member 110, respectively, and redundant description thereof is omitted. Further, the structures not particularly shown are also the same as those of the first exemplary embodiment and redundant description thereof is omitted.

The frame member 120 has the side wall 123 and the first protrusion 121 just like in the first and second exemplary embodiments. The frame member 120 further has a fourth protrusion 127. The fourth protrusion 127 is located lower than the first protrusion 121. The first protrusion 121 and the fourth protrusion 127 protrude inward from the side wall 123. Then, the support part 153 is inserted between the first protrusion 121 and the fourth protrusion 127 and fit therewith. The frame member 120 thereby grasps the third member 150. The width of the end side of the support part 153 that is opposed to the frame member 120 is wider than the breadth of the protrusion 127. In this manner, the frame member 120 fixes the third member 150, thereby allowing grasping or suction. The first protrusion 121 and the fourth protrusion 127 of the frame member 120 serve as a fixation mechanism that fixes the third member 150. In this structure, because the frame member 120 has the fixation mechanism that fixes the third member 150, the third protrusion 114 and the holding part 134 are not needed. The fourth protrusion 127 can be formed by cutting a thin metal plate and partly bending it. Note that a manufacturing method of the mounting board according to this exemplary embodiment is also the same as that of the first exemplary embodiment, and redundant description thereof is omitted.

### (Structure Example)

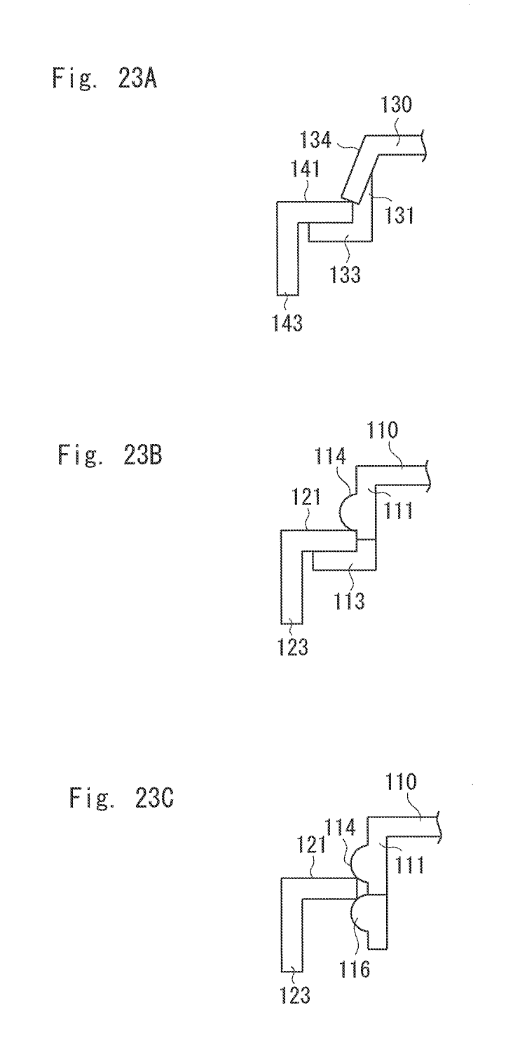

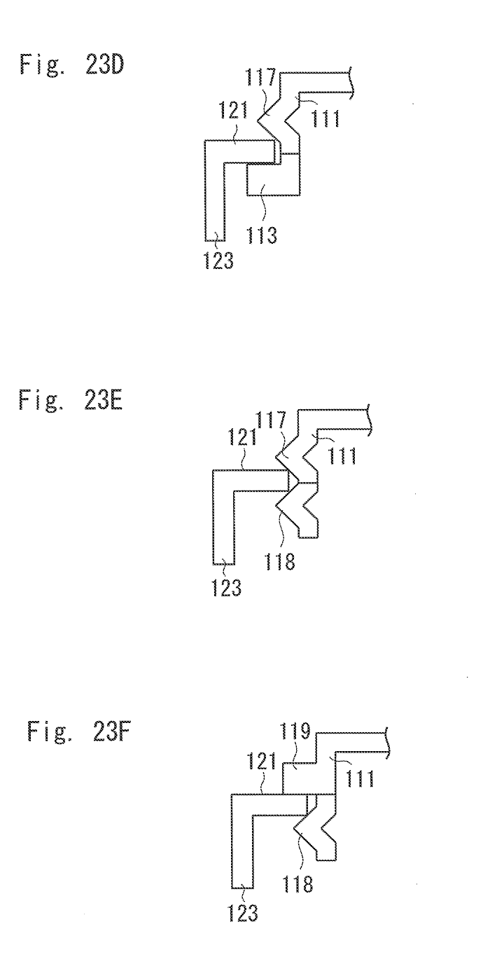

An example of the fitting structure of the frame unit is described hereinafter with reference to FIGS. 23A to 23F. FIGS. 23A to 23F are side cross-sectional views of various holding structures to hold the first protrusion 121 or the first protrusion 141 in between. FIGS. 23A to 23F show six examples (FIGS. 23A to 23F). FIGS. 23A and 23B correspond to the first and second exemplary embodiments. Specifically, FIG. 23A shows the structure in which the first protrusion 141 is grasped by the support part 133 and the holding part 134 as in the second exemplary embodiment, and FIG. 23B shows the structure in which the first protrusion 121 is grasped by the support part 113 and the third protrusion 114.

Further, FIGS. 23C to 23F are views schematically showing the structure to hold the first protrusion like FIGS. 23A and 23B. As shown in FIGS. 23C to 23F, the first protrusion 121 can be held in between in various structures.

For example, the first protrusion 121 may be held between a fifth protrusion 116 and the third protrusion 114 as shown in FIG. 23C. The fifth protrusion 116 is a protruding portion that protrudes outward from the bent part 111 and is placed below the first protrusion 121. Thus, the fifth protrusion 116 substitutes as the support part 113. The third protrusion 114 is placed above the first protrusion 121. For example, the third protrusion 114 is formed in the mid section 115a of the first member 110, and the fifth protrusion 116 is formed in the both end sections 115b of the first member 110. In this manner, the first protrusion 121 is held between the upper and lower protrusions.

The first protrusion 121 may be grasped by the support part 113 and an elbowed part 117 as shown in FIG. 23D. The elbowed part 117 is bent like an elbow in cross section. The elbowed part 117 is placed above the first protrusion 121, and the support part 113 is placed below the first protrusion 121. Thus, the elbowed part 117 substitutes as the third protrusion 114 according to the first exemplary embodiment. The elbowed part 117 is a protruding portion that protrudes outward from the bent part 111. For example, the elbowed part 117 is formed in the mid section 115a of the first member 110, and the support part 113 is formed in the both end sections 115b of the first member 110.

The first protrusion 121 may be grasped using elbowed parts 117 and 118 that are bent like an elbow in cross section as shown in FIG. 23E. The elbowed part 117 is placed above the first protrusion 121, and the elbowed part 118 is placed below the first protrusion 121. Thus, the elbowed part 117 substitutes as the third protrusion 114 according to the first exemplary embodiment, and the elbowed part 118 substitutes as the support part 113 according to the first exemplary embodiment. The elbowed parts 117 and 118 are protruding portions that protrude outward from the bent part 111. For example, the elbowed part 117 is formed in the mid section 115a of the first member 110, and the elbowed part 118 is formed in the both end sections 115b of the first member 110.

Further, a holding part 119 that comes into plane contact with the upper surface of the first protrusion 121 may be formed as shown in FIG. 23F. In FIG. 23F, the holding part 119 is placed above the first protrusion 121, and the elbowed part 118 is placed below the first protrusion 121. Thus, the holding part 119 substitutes as the holding part 134 according to the second exemplary embodiment, and the elbowed part 118 substitutes as the support part 133 according to the second exemplary embodiment. The elbowed part 118 and the holding part 119 are protruding portions that protrude outward from the bent part 111. For example, the holding part 119 is formed in the mid section 115a of the first member 110, and the elbowed part 118 is formed in the both end sections 115b of the first member 110.

In this manner, a structure to hold the first protruding portion is not particularly limited. Further, the structure that is placed above the first protruding portion and the structure that is placed below the first protruding portion may be interchanged as appropriate. To form the holding structure, the protrusion, the elbowed part, the holding part and the support part may be used in any combination. Such a holding structure may be located along the side wall 123 or located scattered at a plurality of positions.

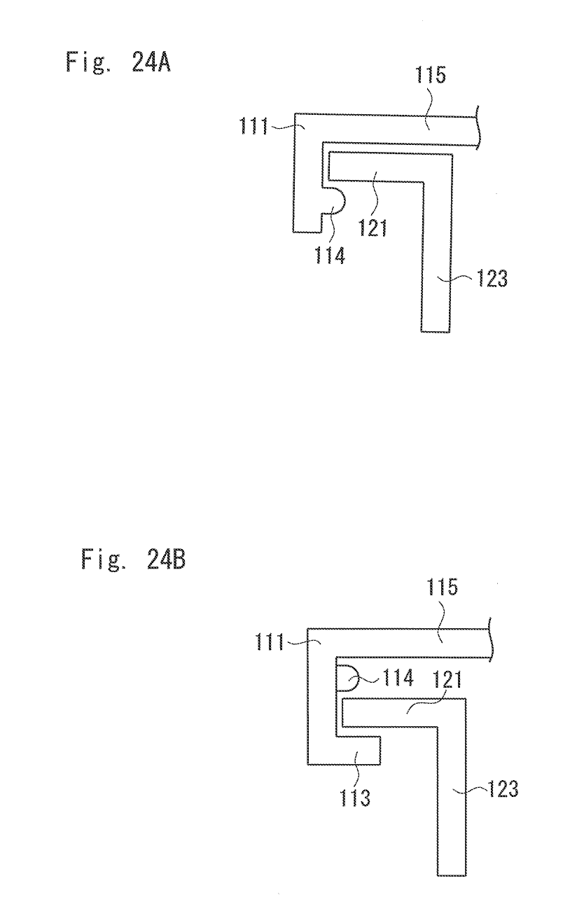

Although the first protrusions 121 and 141 protrude inward (toward the opening) from the side walls 123 and 143, respectively, in the above-described first and second exemplary embodiments, the opposite structure is possible. Specifically, the first protrusions 121 and 141 may protrude outward (toward the outside of the opening) from the side walls 123 and 143, respectively. This structure is described with reference to FIGS. 24A and 24B. FIGS. 24A and 24B are side cross-sectional views showing the structure in which the first protrusion 121 protrudes outward. FIGS. 24A and 24B show two structure examples.

For example, the top surface 115 of the first member has the bent part 111. The top surface 115 further has the third protrusion 114 inside the bent part 111. In this case, the third protrusion 114 protrudes inward under the top surface 115, differently from the first exemplary embodiment. Then, the first protrusion 121 is held between the top surface 115 and the third protrusion 114. In this structure also, the first member 110 can be fixed to the frame member 120.

Alternatively, a metal plate to serve as the first member 110 is bent at two positions into U-shape (FIG. 24B). Then, the first protrusion 121 is inserted into the mouth of the U-shape. Further, in the example shown in FIG. 24B, the third protrusion 114 is placed inside the U-shape. The first protrusion 121 is held between the third protrusion 114 and the support part 113 at the end of the U-shape that protrudes inward from the bent part 111. In this manner, the same effect can be obtained with the structure in which the first protrusion 121 protrudes outward (toward the outside of the opening 125). The first protrusion 121 may protrude outward or inward from the side wall 123. Thus, the structure that protrudes inward (toward the opening) or outward from the side wall 123 is referred to as the first protrusion 121.

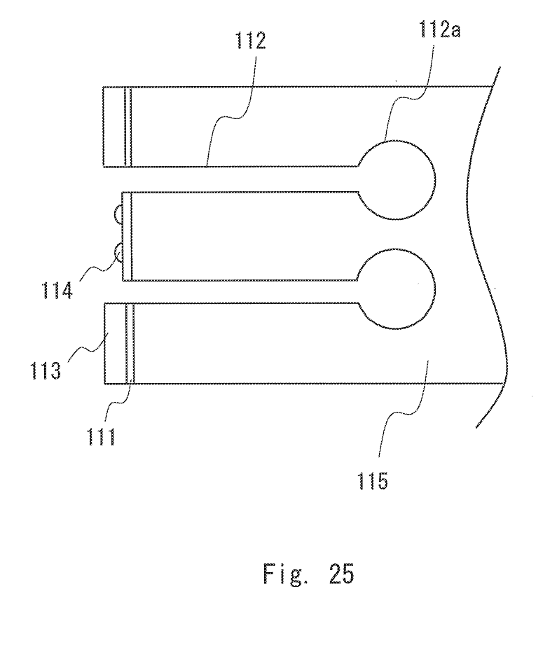

Note that the shape of a cutout in the first member 110, the second member 130 and the third member 150 is not limited to a slit. A cut other than a linear shape may be made on the top surface. FIG. 25 is a top view schematically showing the structure of the first member 110, in which a cutout 112a is added at the end of the slit 112 located opposite from the bent part 111. For example, the first member 110 is easily elastically deformed by providing a circular cutout 112a as shown in FIG. 25. Providing a semi-circular or circular cutout 112a at the end of the slit 112 increases the amount of swing. This allows easy elastic deformation of the first member 110, which facilitates attachment and detachment. The shape of a cutout is not limited to the shown shape as a matter of course.

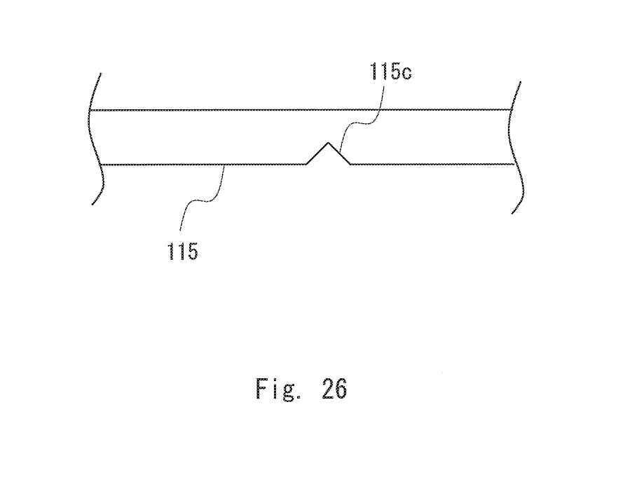

Further, the deformation of the first member 110 or the like may be made easier by partly reducing the thickness of the top surface 115. FIG. 26 is a side view schematically showing the structure of the top surface 115. For example, a depression 115c is formed at a part of the top surface 115 as shown in FIG. 26. Because the strength of the top surface 115 decreases at the position of the depression 115c, the first member 110 is likely to be curved. This allows easy elastic deformation of the first member 110, which facilitates attachment and detachment. Note that the position at which the depression 115c is formed is not particularly limited. For example, it may be formed near the end of the slit 112. The above structures may be combined to make deformation of the first member 110 easier. Further, a depression or cutout may be formed in the same manner in the second member 130 and the third member 150 as well.

### First Alternative Example

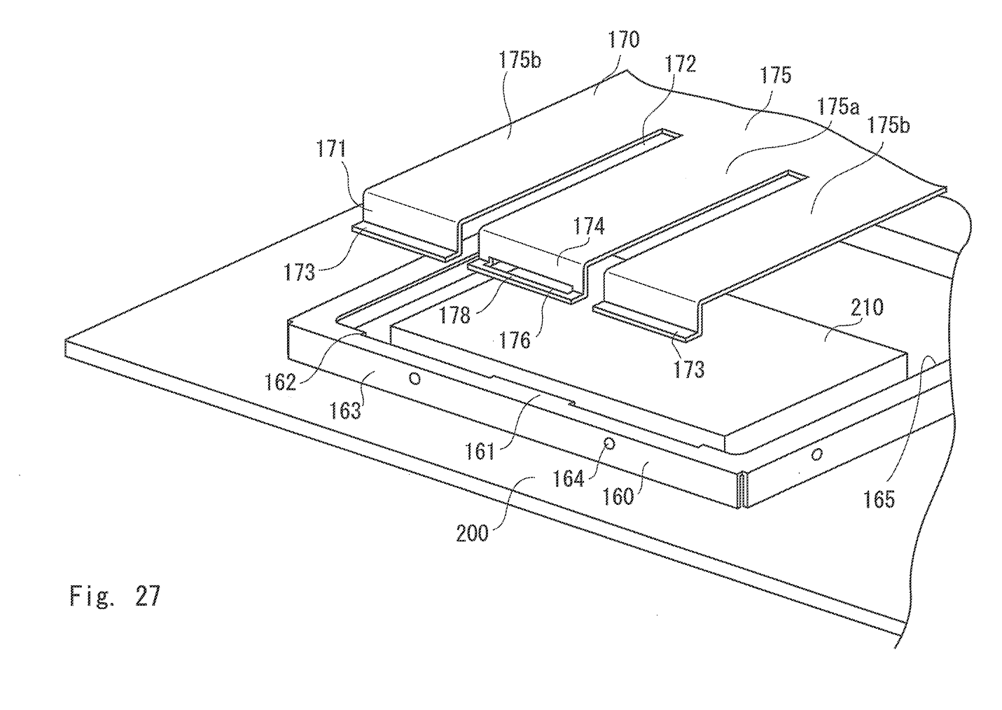

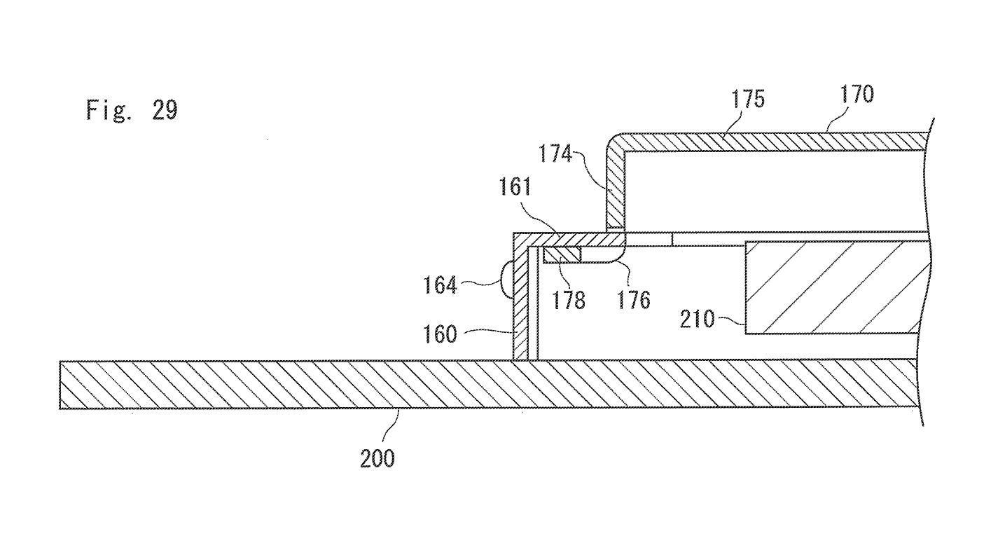

An alternative example of the first exemplary embodiment is described hereinafter with reference to FIGS. 27 to 29. FIG. 27 is an exploded perspective view partly showing a structure of a mounting board unit according to the first alternative example. FIG. 28 is a perspective view partly showing the structure of the mounting board unit according to the first alternative example. FIG. 29 is a side cross-sectional view partly showing the structure of the mounting board unit according to the first alternative example.

In this alternative example, a first member 170 corresponds to the first member 110 according to the first exemplary embodiment, and a frame member 160 corresponds to the frame member 120. Thus, a bent part 171, a slit 172, a support part 173, a top surface 175, a mid section 175a and both end sections 175b of the first member 170 correspond to the bent part 111, the slit 112, the support part 113, the top surface 115, the mid section 115a and the both end sections 115b of the first member 110, respectively. Likewise, a first protrusion 161, a step 162, a side wall 163, a second protrusion 164 and an opening 165 of a frame member 160 correspond to the first protrusion 121, the step 122, the side wall 123, the second protrusion 124 and the opening 125 of the frame member 120, respectively. Thus, the same structures as in the first exemplary embodiment are not redundantly described.

In this alternative example, the mid section 175a has a bent part 174 and a support part 178. The bent part 174 and the support part 178 that is seated outward at its bottom end correspond to the bent part 111 and the support part 113, respectively. Further, an opening 176 is made between the bent part 174 and the support part 178. The opening 176 is formed from the bottom end of the bent part 174 to a part of the support part 178. The first protrusion 161 is inserted into the opening 176, and thereby the frame member 160 and the first member 170 are fixedly fit with each other. A part of the first protrusion 161 which faces the opening 176 protrudes more than a part which faces the support part 173. In this manner, the size of protrusion of the first protrusion 161 partly changes. The plane that delimits the opening 176 has the same function as the third protrusion 114 described in the first exemplary embodiment. Specifically, the first protrusion 161 is held down by the top face of the inner wall of the opening 176 provided in the bent part 174. Further, the support part 173 is provided below the first protrusion 161. In this structure also, the frame member 160 is fit by the first member 170 as in the first exemplary embodiment. Thus, the same effects as in the first exemplary embodiment can be obtained.

### Second Alternative Example

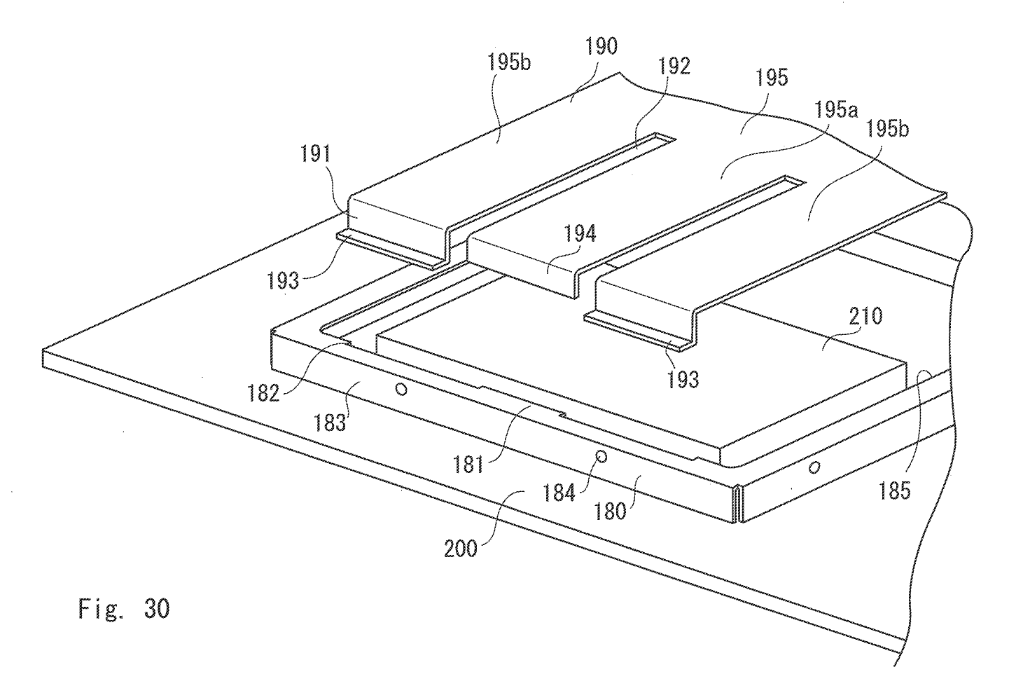

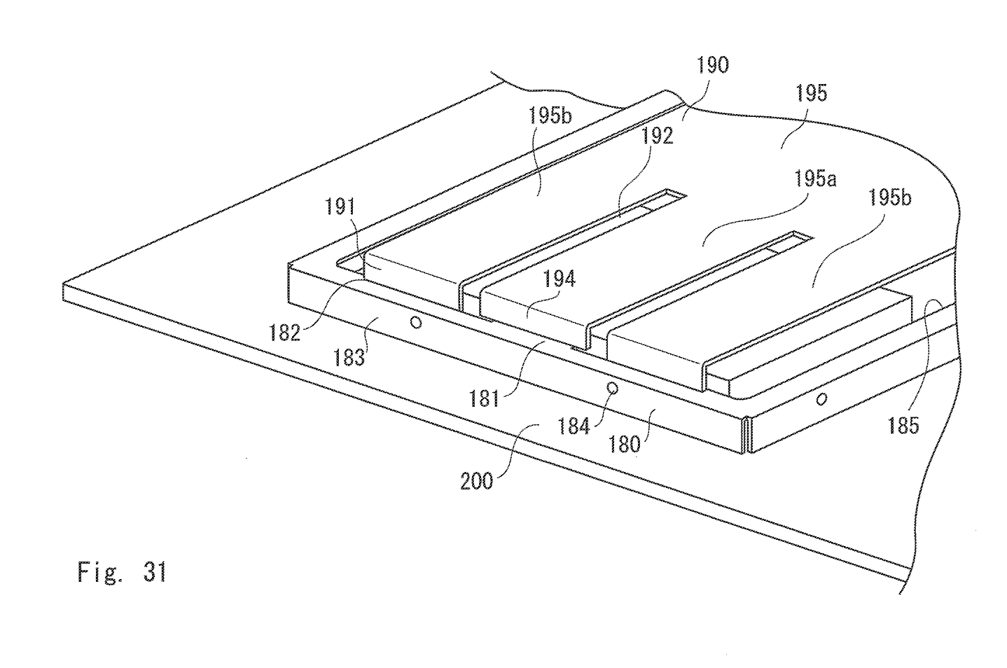

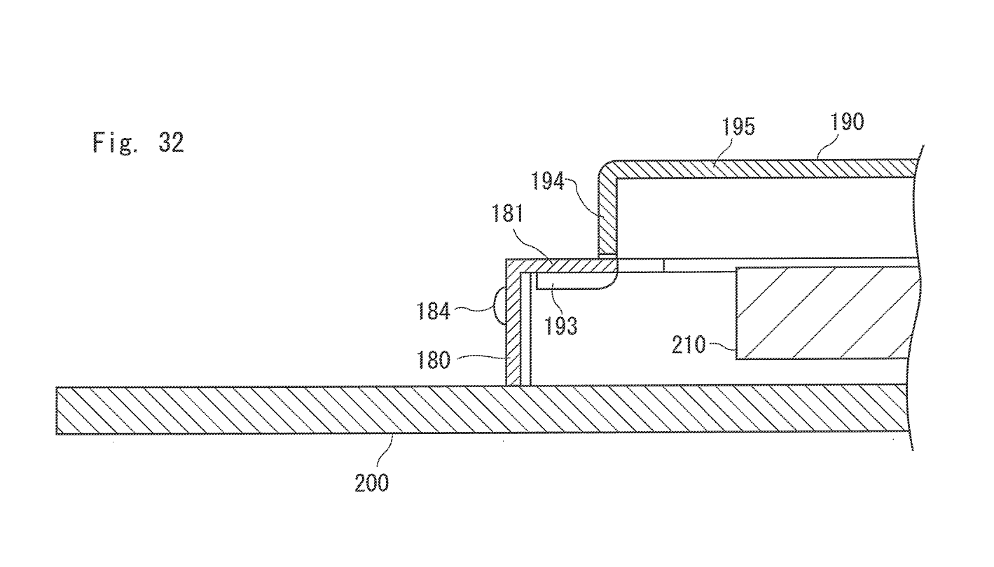

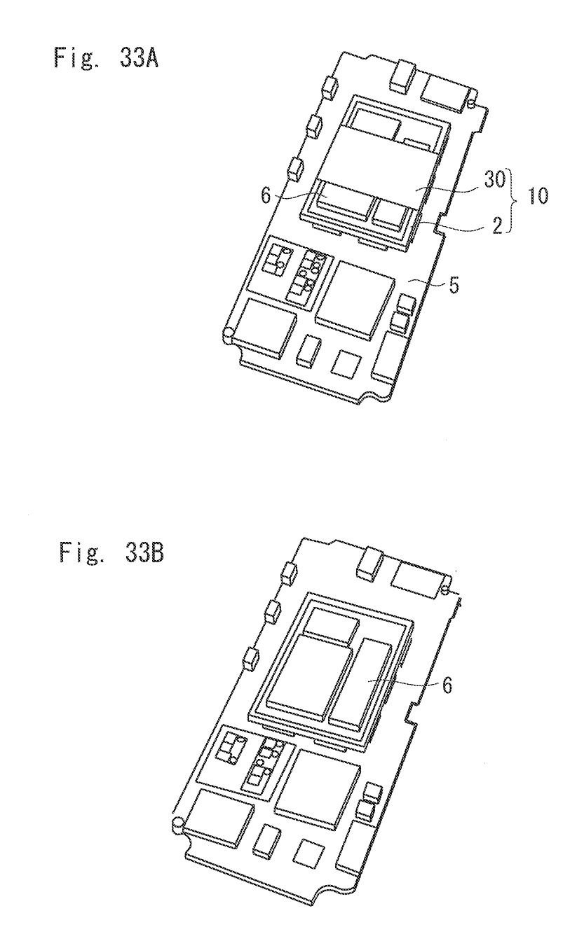

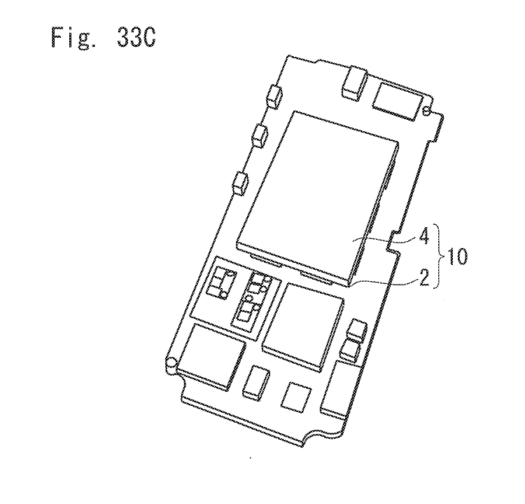

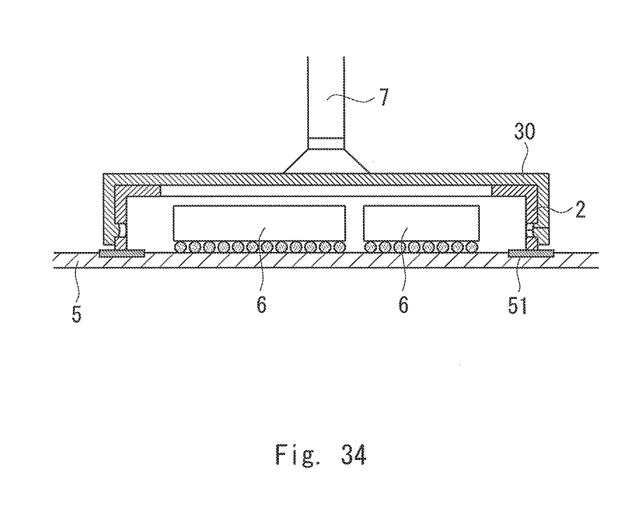

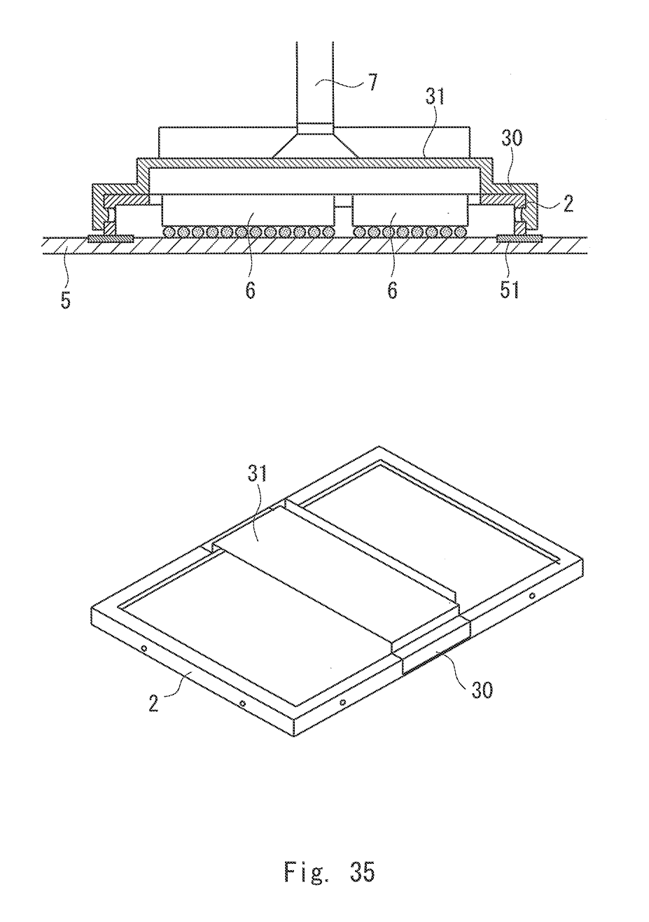

An alternative example of the second exemplary embodiment is described hereinafter with reference to FIGS. 30 to 32. FIG. 30 is an exploded perspective view partly showing a structure of a mounting board unit according to the second alternative example. FIG. 31 is a perspective view partly showing the structure of the mounting board unit according to the second alternative example. FIG. 32 is a side cross-sectional view partly showing the structure of the mounting board unit according to the second alternative example.

In this alternative example, a second member 190 corresponds to the second member 130 according to the second exemplary embodiment, and a frame member 180 corresponds to the frame member 140. Thus, a bent part 191, a slit 192, a support part 193, a holding part 194, a top surface 195, a mid section 195a and both end sections 195b of the second member 190 correspond to the bent part 131, the slit 132, the support part 133, the holding part 134, the top surface 135, the mid section 135a and the both end sections 135b of the second member 130, respectively. Likewise, a first protrusion 181, a step 182, a side wall 183, a second protrusion 184 and an opening 185 of the frame member 180 correspond to the first protrusion 141, the step 142, the side wall 143, the second protrusion 144 and the opening 145 of the frame member 140, respectively. Thus, the same structures as in the second exemplary embodiment are not redundantly described.

In this alternative example, the mid section 195a has the holding part 194. The holding part 194 corresponds to the holding part 134. The holding part 194 holds down the first protrusion 181. Further, the support part 193 is placed below the first protrusion 181. The frame member 180 is thereby fixedly fit with the second member 190. In this alternative example, the holding part 194 extends from the top surface 195 along the direction substantially perpendicular to the board 200. A part of the first protrusion 181 which faces the holding part 194 protrudes more than a part which faces the support part 193. Further, the support part 193 is placed below the first protrusion 181. In this structure also, the frame member 180 is fit by the second member 190 as in the second exemplary embodiment. Thus, the same effects as in the second exemplary embodiment can be obtained.

The above-described mounting board unit is suitable for portable devices such as mobile telephones. Further, two or more electronic components such as a semiconductor chip, for example, may be placed in the frame member. The present invention is not restricted to the above-described exemplary embodiments, and various changes and modifications may be made without departing from the scope of the invention. Further, the exemplary embodiments and alternative embodiments can be combined as desirable.

Although several exemplary embodiments of the present invention are described above, the present invention is not restricted thereto. The structures and details of the present invention are susceptible of numerous changes and modifications as known to those skilled in the art within the scope of the present invention.

This application is based upon and claims the benefit of priority from Japanese patent application No. 2010-86154, filed on Apr. 2, 2010, the disclosure of which is incorporated herein in its entirety by reference.

### INDUSTRIAL APPLICABILITY

The present invention is suitably applicable to a frame member, a frame unit, a mounting board unit, and a manufacturing method for a mobile terminal or the like.

### REFERENCE SIGNS LIST

2 FRAME MEMBER
6 ELECTRONIC COMPONENT
30 SUCTION MEMBER
100 FRAME UNIT
110 FIRST MEMBER
111 BENT PART
112 SLIT
112A CUTOUT
113 SUPPORT PART
114 THIRD PROTRUSION
115 TOP SURFACE
115A MID SECTION
115B BOTH END SECTION
115C DEPRESSION
116 FIFTH PROTRUSION
117 ELBOWED PART
118 ELBOWED PART
119 HOLDING PART
120 FRAME MEMBER
121 FIRST PROTRUSION
122 STEP
123 SIDE WALL
124 SECOND PROTRUSION
125 OPENING
127 FOURTH PROTRUSION
130 FIRST MEMBER
131 BENT PART
132 SLIT
133 SUPPORT PART
134 HOLDING PART
135 TOP SURFACE
135A MID SECTION
135B BOTH END SECTION
140 FRAME MEMBER
141 FIRST PROTRUSION
142 STEP
143 SIDE WALL
144 PROTRUSION
145 OPENING
150 SECOND MEMBER
151 BENT PART
153 SUPPORT PART
155 TOP SURFACE
160 FRAME MEMBER
161 FIRST PROTRUSION
162 STEP
163 SIDE WALL
164 SECOND PROTRUSION
165 OPENING
170 FIRST MEMBER
171 BENT PART
172 SLIT
173 SUPPORT PART
174 BENT PART
175 TOP SURFACE
175A MID SECTION
175B BOTH END SECTION
176 OPENING
178 SUPPORT PART
180 FRAME MEMBER
181 FIRST PROTRUSION
182 STEP
183 SIDE WALL
184 SECOND PROTRUSION
185 OPENING
190 SECOND MEMBER
191 BENT PART
192 SLIT
193 SUPPORT PART
194 HOLDING PART
195 TOP SURFACE
195A MID SECTION
195B BOTH END SECTION
200 BOARD
210 ELECTRONIC COMPONENT
220 SOLDER
230 SOLDER
300 SHIELD COVER
310 HOLE

1. A frame unit to be attached to a mounting board on which an electronic component is mounted, comprising:
a frame member having an opening where the electronic component is placed, a side wall to be connected to the mounting board, and a first protruding portion protruding inward or outward from the side wall; and
a first member detachably attached to the frame member and having a second protruding portion protruding toward the frame member to fit with the first protruding portion.

2. The frame unit according to claim 1, wherein the second protruding portion of the first member is placed above and below the first protruding portion to fit with the first protruding portion.

3. The frame unit according to claim 1, wherein the first protruding portion of the frame member is placed above and below the second protruding portion to fit with the second protruding portion.

4. The frame unit according to claim 1, wherein the first protruding portion of the frame member has a step to restrict a position of the first member.

5. The frame unit according to claim 4, wherein the first protruding portion of the frame member protrudes toward the opening on both sides of the first member, to form the step.

6. The frame unit according to claim 1, wherein the first member has a cutout.

7. The frame unit according to claim 1, wherein the side wall has a protrusion or a depression on an outside.

8. The frame unit according to claim 1, wherein
the frame member has a rectangular frame shape, and
the first member fits with the first protruding portion on two side walls excluding two opposed side walls of the frame member.

9. The frame unit according to claim 1 wherein the first member is grasped or sucked by a grasping mechanism or a suction mechanism for placing the frame member onto the board.

10. A frame unit to be attached to a mounting board on which an electronic component is mounted, comprising:
a frame member having an opening where the electronic component is placed, a side wall to be connected to the mounting board, and a first protruding portion protruding inward or outward from the side wall; and
a second member detachably attached to the frame member and having a holding part placed above the first protruding portion and a support part placed below the first protruding portion to grasp the first protruding portion.

11. The frame unit according to claim 10, wherein
the second member has a top surface facing the board, and
the holding part extends from the top surface along a direction substantially perpendicular to the board.

12. The frame unit according to claim 11, wherein
the second member has a top surface facing the board, and
the holding part extends from the top surface to become wider toward the board.

13. A mounting board unit comprising:
a frame unit according to claim 1;
a board to which the frame unit is attached; and
an electronic component mounted on the board inside the frame unit.

14. A mounting board unit on which an electronic component is mounted, comprising:
a board;
an electronic component mounted on the board;
a frame member having a side wall surrounding the electronic component, and a first protruding portion protruding inward or outward from the side wall and fit by a first member detachably attached to the frame member; and
solder applied all around the frame member to connect the frame member to the board.

15. The mounting board unit according to claim 13, further comprising:
a shield cover attached to the frame member to shield the electronic component.

16. A manufacturing method of a mounting board unit on which an electronic component and a frame member surrounding the electronic component are mounted, comprising:
preparing a frame member having a side wall to delimit an opening where the electronic component is placed and a first protruding portion protruding inward or outward from the side wall;
fixing a first member to the frame member by fitting the first member having a second protruding portion with the first protruding portion;
placing the frame member onto the board by sucking or grasping the first member using a suction mechanism or a grasping mechanism;
mounting the frame member on the board; and
detaching the first member from the frame member.

17. The manufacturing method of a mounting board unit according to claim 16, further comprising:
attaching a shield cover for shielding the electronic component to the frame member from which the first member is detached.

18. A manufacturing method of a mounting board unit on which an electronic component and a frame member surrounding the electronic component are mounted, comprising:
preparing a frame member having a side wall to delimit an opening where the electronic component is placed and a first protruding portion protruding inward or outward from the side wall;
fixing a second member to the frame member by holding the first protruding portion between a holding part and a support part of the second member;
placing the frame member onto the board by sucking or grasping the second member using a suction mechanism or a grasping mechanism;
mounting the frame member on the board; and
detaching the second member from the frame member.

19. The manufacturing method of a mounting board unit according to claim 16, wherein the frame member is fixed to the board by solder applied all around the frame member.
